(19) United States
(12) Patent Application Publication
(10) Pub. No.: US 2023/0242556 A1
(43) Pub. Date: Aug. 3, 2023

(54) NOVEL METHOD FOR MANUFACTURING DEUTERATED BORON COMPOUND

(71) Applicant: SFC CO., LTD., Cheongju-si (KR)

(72) Inventors: Bong-Ki SHIN, Cheongju-si (KR); Sung-Hoon JOO, Cheongju-si (KR); Ji-Hwan KIM, Cheongju-si (KR); Jun-Young MOON, Cheongju-si (KR)

(21) Appl. No.: 18/155,343

(22) Filed: Jan. 17, 2023

(30) Foreign Application Priority Data
Jan. 28, 2022 (KR) 10-2022-0013428

(51) Int. Cl. C07F 5/02; C09K 11/06; H10K 85/60

(52) U.S. Cl. CPC C07F 5/027; C09K 11/06; H10K 85/658; C09K 2211/1022; C09K 2211/1007; C09K 2211/1014; C07B 2200/05; H10K 50/11

(57) ABSTRACT

The present disclosure relates to a novel method for manufacturing a deuterated boron compound and, more specifically, to a novel method for manufacturing a boron compound including a heteroaromatic ring, whereby the deuterated polycyclic ring compound guarantees excellent longevity as a dopant material in a light-emitting layer for the organic light-emitting diode and can be produced at high yield, with the improvement of facilitation and economy in the process due to the single deuteration step for the specific intermediate.

### CROSS-REFERENCE TO RELATED APPLICATIONS

This application claims the priority of the Korean Patent Applications NO 10-2022-0013428, filed on Jan. 28, 2022, in the Korean Intellectual Property Office. The entire disclosure of this application is hereby incorporated by reference.

### BACKGROUND OF THE INVENTION

### 1. Field of the Invention

The present disclosure relates to a novel method for manufacturing a deuterated boron compound and, more specifically, to a novel method for manufacturing a boron compound including a heteroaromatic ring, at least carbon atom of which has a deuterium atom as a substituent.

### 2. Description of the Related Art

Organic light-emitting diodes, based on self-luminescence, exhibit the advantages of having a wide viewing angle, excellent contrast, fast response time, high brightness, excellent driving voltage and response rate characteristics, and of allowing for a polychromic display.

A typical organic light-emitting diode includes a positive electrode (anode) and a negative electrode (cathode), facing each other, with an organic emissive layer disposed therebetween.

As to the general structure of the organic light-emitting diode, a hole transport layer, a light-emitting layer, an electron transport layer, and a cathode are formed in that order on an anode. Here, all of the hole transport layer, the light-emitting layer, and the electron transport layer are organic films comprising organic compounds.

An organic light-emitting diode having such a structure operates as follows: when a voltage is applied between the anode and the cathode, the anode injects holes which are then transferred to the light-emitting layer via the hole transport layer while electrons injected from the cathode move to the light-emitting layer via the electron transport layer. In the luminescent zone, the carriers such as holes and electrons recombine to produce an exciton. When the exciton returns to the ground state from the excited state, the molecule of the light-emitting layer emits light.

Materials used as the organic layers in organic light-emitting diodes may be divided according to functions into luminescent materials and charge carrier materials, for example, a hole injection material, a hole transport material, an electron injection material, and an electron transport material. The light-emitting mechanism forms the basis of classification of luminescent materials as fluorescent and phosphorescent materials, which use excitons in singlet and triplet states, respectively.

When a single material is employed as the luminescent material, intermolecular actions cause the maximum luminescence wavelength to shift toward a longer wavelength, resulting in a reduction in color purity and light emission efficiency due to light attenuation. In this regard, a host-dopant system may be used as a luminescent material so as to increase the color purity and the light emission efficiency through energy transfer. This is based on the principle whereby, when a dopant which is smaller in energy band gap than a host forming a light-emitting layer is added in a small amount to the light-emitting layer, excitons are generated from the light-emitting layer and transported to the dopant, emitting light at high efficiency. Here, light with desired wavelengths can be obtained depending on the kind of the dopant because the wavelength of the host moves to the wavelength range of the dopant.

Studies have been conducted to introduce a deuterium-substituted compound as a material in the light emitting layer in order to improve the longevity and stability of the organic light emitting diode.

Compounds substituted with deuterium are known to exhibit differences in thermodynamic behavior from those bonded with hydrogen because the atomic mass of deuterium is twice as great as that of hydrogen, which results in lower zero point energy and lower vibration energy level.

In addition, physicochemical properties involving deuterium, such as chemical bond lengths, etc., appear to be different from those involving hydrogen. In particular, the van der Waals radius of deuterium is smaller than that of hydrogen because of the smaller stretching amplitude of the C-D bond compared to the C—H bond. Generally, the C-D bond is shorter and stronger than the C—H bond. Upon deuterium substitution, the ground state energy is lowered and a short bond length is formed between the carbon atom and the deuterium atom. Accordingly, the molecular hardcore volume becomes smaller, thereby reducing the electron polarizability can be reduced, and the thin film volume can be increased by weakening the intermolecular interaction.

As discussed above, deuterium substitution provides the effect of reducing the crystallinity of the thin film, that is, it makes the thin film amorphous. Generally, a compound having deuterium substitution may be advantageously used to increase the lifespan and driving characteristics of an OLED and further improve the thermal resistance.

Recently, many studies have been conducted on boron compounds as dopant compounds in the light emitting layer. With respect to related arts, reference may be made to Korean Patent No. 10-2148296 (Aug. 26, 2020), which discloses an organic light-emitting diodes using, as a dopant in the light emitting layer, a fused polycyclic compound that contains at least one 5-membered ring, with a boron atom serving as a central atom bonded to the aromatic rings. However, the deuteration of specific ring moieties in the fused polycyclic ring compound is not concretely elucidated anywhere in the document.

In spite of various efforts, including the techniques of the cited document, made to manufacture dopant compounds exhibiting longevity characteristics, there is a still continuing need for development of a method for manufacturing a compound having a deuterium atom introduced into a specific ring moiety of the fused polycyclic rings thereof.

### RELATED ART DOCUMENT

Korean Patent No. 10-2148296 (Aug. 26, 20206)

### SUMMARY OF THE INVENTION

Therefore, the present disclosure is to provide a novel method for manufacturing a boron compound available as a dopant in a light-emitting layer of an organic light-emitting diode (OLED).

To achieve the technical purpose, the present disclosure provides a method for manufacturing a polycyclic ring compound, the method including the steps of: a) deuterating a compound represented by [Intermediate A-1] to prepare a compound represented by [Intermediate A-2]; and b) preparing a compound represented by [Chemical Formula A] or [Chemical Formula B] from the compound represented by [Intermediate A-2]:

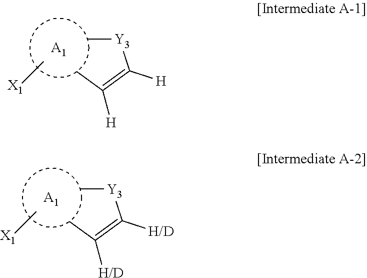

wherein,

X₁ is any one halogen element selected from among F, Cl, Br, and I,

Y₃ is any one selected from among N—R₁, CR₂R₃, O, S, Se, and SiR₄R₅,

wherein the substituents R₁ to R₅, which may be same or different, are as defined in [Chemical Formula A] and [Chemical Formula B],

A₁ is a substituted or unsubstituted aromatic ring of 6 to 50 carbon atoms or a substituted or unsubstituted heteroaromatic ring of 2 to 50 carbon atoms,

at least one of the hydrogen atoms bonded to the aromatic carbon atoms of the A₁ ring in [Intermediate A-2] is substituted by a deuterium atom,

H/D means that a hydrogen atom or a deuterium atom bonds to a carbon atom;

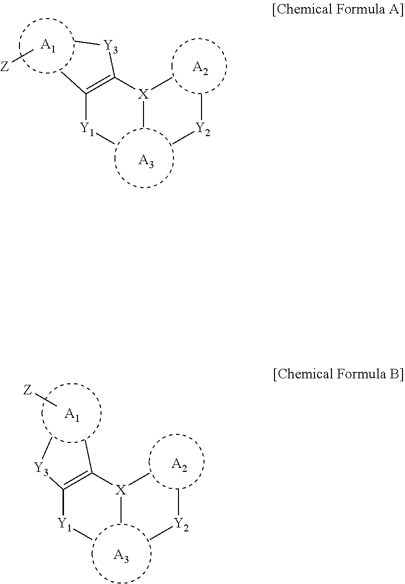

wherein,

A₁'s, which may be same or different, are each independently a substituted or unsubstituted aromatic ring of 6 to 50 carbon atoms or a substituted or unsubstituted heteroaromatic ring of 2 to 50 carbon atoms, with at least one aromatic carbon atom of the A₁ ring moiety being deuterated,

A₂ and A₃, which may be same or different, are each independently at least one selected from among a substituted or unsubstituted aromatic ring of 6 to 50 carbon atoms, a substituted or unsubstituted aliphatic ring-fused aromatic ring of 8 to 50 carbon atoms, a substituted or unsubstituted heteroaromatic ring of 2 to 50 carbon atoms, and a substituted or unsubstituted aliphatic ring-fused heteroaromatic ring of 4 to 50 carbon atoms,

X is any one selected from among B, P, P═O, and P═S,

Z is a substituent for X₁ of [Intermediate A-2], and is selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, and a halogen atom,

Y₁ to Y₃, which may be same or different, are each independently any one selected from among N—R₁, CR₂R₃, O, S, Se, and SiR₄R₅,

wherein R₁ to R₅, which may be same or different, are each independently any one selected from a hydrogen atom, a deuterium atom, a substituted or unsubstituted alkyl of 1 to 30 carbon atoms, a substituted or unsubstituted alkenyl of 2 to 24 carbon atoms, a substituted or unsubstituted alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen,

a bond may be formed between R₂ and R₃ to additionally form a mono- or polycyclic aliphatic or aromatic ring, and/or a bond may be formed between R₄ and R₅ to additionally form a mono- or polycyclic aliphatic or aromatic ring,

at least any one of R₁ to R₅ in Y₁ may bond to the A₃ ring moiety to additionally form a mono- or polycyclic aliphatic or aromatic ring,

at least any one of R₁ to R₅ in Y₂ may bond to the A₂ or A₃ ring moiety to additionally form a mono- or polycyclic aliphatic or aromatic ring,

at least any one of R₁ to R₅ in Y₃ may bond to the A₁ ring moiety to additionally form a mono- or polycyclic aliphatic or aromatic ring, and

in [Chemical Formula B],

at least any one of R₁ to R₅ in Y₁ may bond to at least any one of R₁ to R₅ in Y₃ to additionally form a mono- or polycyclic aliphatic or aromatic ring,

wherein the term ‘substituted’ in the expression “a substituted or unsubstituted” in [Intermediate A-1], [Intermediate A-2], [Chemical Formula A] and [Chemical Formula B] means having at least one substituent selected from the group consisting of a deuterium atom, a cyano, a halogen, a hydroxy, a nitro, an alkyl of 1 to 24 carbon atoms, a deuterated alkyl of 1 to 24 carbon atoms, a halogenated alkyl of 1 to 24 carbon atoms, an alkenyl of 2 to 24 carbon atoms, an alkynyl of 2 to 24 carbon atoms, a cycloalkyl of 3 to 24 carbon atoms, a deuterated cycloalkyl of 3 to 24 carbon atoms, a heteroalkyl of 1 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, a heteroarylalkyl of 2 to 24 carbon atoms, a deuterated heteroarylalkyl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, a deuterated aryloxy of 6 to 24 carbon atoms, an arylthionyl of 6 to 24 carbon atoms, and a deuterated arylthionyl of 6 to 24 carbon atoms.

The method for manufacturing a polycyclic compound according to the present disclosure, which breaks away from the conventional multi-step processes for introducing deuterium into a polycyclic ring, is designed to use, as an intermediate, a deuterated aryl halide or heteroaryl halide prepared through deuteration of an aryl halide or heteroaryl halide to introduce a deuterium atom into a boron dopant compound, whereby a deuterated boron dopant compound can be produced at high yield, with the improvement of facilitation and economy in the process.

### DETAILED DESCRIPTION OF THE EXEMPLARY EMBODIMENTS

Hereinafter, exemplary embodiments which can be easily implemented by those skilled in the art will be described with reference to the accompanying drawing.

In each drawing of the present disclosure, sizes or scales of components may be enlarged or reduced from their actual sizes or scales for better illustration, and known components may not be depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In drawings, for convenience of description, sizes of components may be exaggerated for clarity. For example, since sizes and thicknesses of components in drawings are arbitrarily shown for convenience of description, the sizes and thicknesses are not limited thereto. Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between” may be used herein for ease of description to refer to the relative positioning.

Throughout the specification, when a portion may “comprise” or “include” a certain constituent element, unless explicitly described to the contrary, it may not be construed to exclude another constituent element but may be construed to further include other constituent elements. Further, throughout the specification, the word “on” means positioning on or below the object portion, but does not essentially mean positioning on the lower side of the object portion based on a gravity direction.

The present disclosure is drawn to a novel method for preparation of a polycyclic boron compound available as a dopant in a light-emitting layer of an organic light-emitting diode designed to be improved in longevity, wherein a deuterated aryl halide or a deuterated heteroaryl halide is prepared by subjecting an aryl halide or a heteroaryl halide to deuteration and then used as an intermediate to increase the synthesis yield of the final product polycyclic ring compound, whereby the overall reaction processes necessary for the production of the finally synthesized boron dopant compound can be simplified and the product can be mass produced at high yield.

In greater detail, the present disclosure provides a method for manufacturing a polycyclic ring compound, the method including the steps of: a) deuterating a compound represented by [Intermediate A-1] to prepare a compound represented by [Intermediate A-2]; and b) preparing a compound represented by [Chemical Formula A] or [Chemical Formula B] from the compound represented by [Intermediate A-2]:

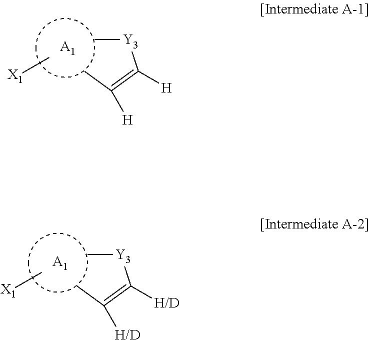

X₁ is any one halogen element selected from among F, Cl, Br, and I,

Y₃ is any one selected from among N—R₁, CR₂R₃, O, S, Se, and SiR₄R₅,

wherein the substituents R₁ to R₅, which may be same or different, are as defined in [Chemical Formula A] and [Chemical Formula B],

A₁ is a substituted or unsubstituted aromatic ring of 6 to 50 carbon atoms or a substituted or unsubstituted heteroaromatic ring of 2 to 50 carbon atoms,

at least one of the hydrogen atoms bonded to the aromatic carbon atoms of the A₁ ring in [Intermediate A-2] is substituted by a deuterium atom,

H/D means that a hydrogen atom or a deuterium atom bonds to a carbon atom

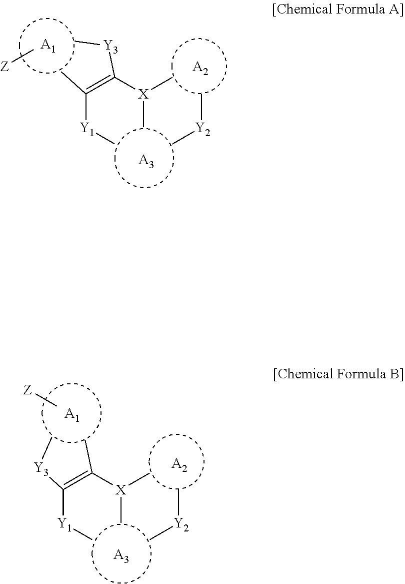

wherein,

A₁'s, which may be same or different, are each independently a substituted or unsubstituted aromatic ring of 6 to 50 carbon atoms or a substituted or unsubstituted heteroaromatic ring of 2 to 50 carbon atoms, with at least one aromatic carbon atom of the A₁ ring moiety being deuterated,

A₂ and A₃, which may be same or different, are each independently at least one selected from among a substituted or unsubstituted aromatic ring of 6 to 50 carbon atoms, a substituted or unsubstituted aliphatic ring-fused aromatic ring of 8 to 50 carbon atoms, a substituted or unsubstituted heteroaromatic ring of 2 to 50 carbon atoms, and a substituted or unsubstituted aliphatic ring-fused heteroaromatic ring of 4 to 50 carbon atoms,

X is any one selected from among B, P, P═O, and P═S,

Z is a substituent for X₁ of [Intermediate A-2], and is selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, and a halogen atom,

Y₁ to Y₃, which may be same or different, are each independently any one selected from among N—R₁, CR₂R₃, O, S, Se, and SiR₄R₅,

wherein R₁ to R₅, which may be same or different, are each independently any one selected from a hydrogen atom, a deuterium atom, a substituted or unsubstituted alkyl of 1 to 30 carbon atoms, a substituted or unsubstituted alkenyl of 2 to 24 carbon atoms, a substituted or unsubstituted alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen,

a bond may be formed between R₂ and R₃ to additionally form a mono- or polycyclic aliphatic or aromatic ring and/or a bond may be formed between R₄ and R₅ to additionally form a mono- or polycyclic aliphatic or aromatic ring,

any of the substituents R₁ to R₅ in Y₁ may bond to the A₃ ring moiety to form an additional mono- or polycyclic aliphatic or aromatic ring,

any of the substituents R₁ to R₅ in Y₂ may bond to the A₂ or A₃ ring moiety to form an additional mono- or polycyclic aliphatic or aromatic ring,

any of the substituents R₁ to R₅ in Y₃ may bond to the A₁ ring moiety to additionally form an additional mono- or polycyclic aliphatic or aromatic ring, and

in [Chemical Formula B],

at least any one of R₁ to R₅ in Y₁ may bond to at least any one of R₁ to R₅ in Y₃ to additionally form a mono- or polycyclic aliphatic or aromatic ring,

wherein the term ‘substituted’ in the expression “a substituted or unsubstituted” in [Intermediate A-1], [Intermediate A-2], [Chemical Formula A] and [Chemical Formula B] means having at least one substituent selected from the group consisting of a deuterium atom, a cyano, a halogen, a hydroxy, a nitro, an alkyl of 1 to 24 carbon atoms, a deuterated alkyl of 1 to 24 carbon atoms, a halogenated alkyl of 1 to 24 carbon atoms, an alkenyl of 2 to 24 carbon atoms, an alkynyl of 2 to 24 carbon atoms, a cycloalkyl of 3 to 24 carbon atoms, a deuterated cycloalkyl of 3 to 24 carbon atoms, a heteroalkyl of 1 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, a heteroarylalkyl of 2 to 24 carbon atoms, a deuterated heteroarylalkyl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, a deuterated aryloxy of 6 to 24 carbon atoms, an arylthionyl of 6 to 24 carbon atoms, and a deuterated arylthionyl of 6 to 24 carbon atoms.

The expression indicating the number of carbon atoms, such as “a substituted or unsubstituted alkyl of 1 to 30 carbon atoms”, “a substituted or unsubstituted aryl of 5 to 50 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical derived from an aromatic hydrocarbon by removing one hydrogen that is bonded to the aromatic hydrocarbon. Further, the aromatic system may include a fused ring that is formed by adjacent substituents on the aryl radical.

Concrete examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl at least one hydrogen atom of which may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 carbon atoms, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 1 to 24 carbon atoms, an alkynyl of 1 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The substituent heteroaryl used in the compound of the present disclosure refers to a cyclic aromatic system of 2 to 24 carbon atoms bearing as ring members one to three heteroatoms selected from among N, O, P, Si, S, Ge, Se, and Te. In the aromatic system, two or more rings may be fused. One or more hydrogen atoms on the heteroaryl may be substituted by the same substituents as on the aryl.

In addition, the term “heteroaromatic ring”, as used herein, refers to an aromatic ring bearing as aromatic ring members 1 to 3 heteroatoms selected particularly from N, O, P, Si, S, Ge, Se, and Te.

As used herein, the term “alkyl” refers to an alkane missing one hydrogen atom and includes linear or branched structures. Examples of the alkyl substituent useful in the present disclosure include methyl, ethyl, propyl, isopropyl, isobutyl, sec-butyl, tert-butyl, pentyl, isoamyl, and hexyl. At least one hydrogen atom of the alkyl may be substituted by the same substituent as in the aryl.

The term “cyclo” as used in substituents of the present disclosure, such as cycloalkyl, cycloalkoxy, etc., refers to a structure responsible for a mono- or polycyclic ring of saturated hydrocarbons such as alkyl, alkoxy, etc. Concrete examples of cycloalkyl radicals include cyclopropyl, cyclobutyl, cyclopentyl, cyclohexyl, methylcyclopentyl, methylcyclohexyl, ethylcyclopentyl, ethylcyclohexyl, adamantyl, dicyclopentadienyl, decahydronaphthyl, norbornyl, bornyl, and isobornyl. One or more hydrogen atoms on the cycloalkyl may be substituted by the same substituents as on the aryl and it can be applied to cycloalkoxy, as well.

In addition, the term “heterocycloalkyl”, as used herein, refers to a cycloalkyl structure bearing as a ring members one to three heteroatoms selected particularly from among N, O, P, S, Si, Ge, Se, and Te.

The term “alkoxy” as used in the compounds of the present disclosure refers to an alkyl or cycloalkyl singularly bonded to oxygen. Concrete examples of the alkoxy include methoxy, ethoxy, propoxy, isobutoxy, sec-butoxy, pentoxy, iso-amyloxy, hexyloxy, cyclobutyloxy, cyclopentyloxy, adamantyloxy, dicyclopentyloxy, bornyloxy, and isobornyloxy. One or more hydrogen atoms on the alkoxy may be substituted by the same substituents as on the aryl.

Concrete examples of the arylalkyl used in the compounds of the present disclosure include phenylmethyl (benzyl), phenylethyl, phenylpropyl, naphthylmethyl, and naphthylethyl. One or more hydrogen atoms on the arylalkyl may be substituted by the same substituents as on the aryl.

As used herein, the term “alkenyl” refers to an unsaturated hydrocarbon group that contains a carbon-carbon double bond between two carbon atoms and the term “alkynyl” refers to an unsaturated hydrocarbon group that contains a carbon-carbon triple bond between two carbon atoms.

As used herein, the term “alkylene” refers to an organic aliphatic radical regarded as derived from a linear or branched saturated hydrocarbon alkane by removal of two hydrogen atoms from different carbon atoms. Concrete examples of the alkylene include methylene, ethylene, propylene, isopropylene, isobutylene, sec-butylene, tert-butylene, pentylene, iso-amylene, hexylene, and so on. One or more hydrogen atoms on the alkylene may be substituted by the same substituents as on the aryl.

The term “amine” radical, as used herein, is intended to encompass —NH₂, an alkylamine, an arylamine, an alkylarylamine, an arylheteroarylamine, a heteroarylamine, and the like. An arylamine refers to an amine in which one or two of the hydrogen atoms in —NH₂ are substituted by aryls; an alkylamine to an amine in which one or two of the hydrogen atoms in —NH₂ are substituted by alkyls; an alkylarylamine to an amine in which two of the hydrogen atoms in —NH₂ are substituted by an alkyl and an aryl, respectively; an arylheteroarylamine to an amine in which one or two of the hydrogen atoms in —NH₂ are substituted by an aryl and a heteroaryl, respectively; a heteroarylamine to an amine in which both of the hydrogen atoms in —NH₂ are substituted by a heteroaryl. Examples of the arylamine include a substituted or unsubstituted monoarylamine and a substituted or unsubstituted diarylamine. Such nomenclatures of mono- and di-suffixes are true of the alkylamine and the heteroarylamine.

Here, the aryl in each of the arylamine, heteroarylamine, and arylheteroarylamine may be monocyclic aryl or polycyclic aryl, and the heteroaryl in each of the arylamine, the heteroarylamine, and the aylheteroarylamine may be monocyclic heteroaryl or polycyclic heteroaryl.

The term “silyl” radical, as used herein, is intended to encompass —SiH₃, an alkylsilyl, an arylsilyl, an alkyl arylsilyl, an arylheteroarylsilyl, and a heteroarylsilyl. An arylsilyl refers to a silyl in which at least one of the hydrogen atoms in —SiH₃ is substituted by an aryl. An alkylsilyl refers to a silyl in which at least one of the hydrogen atoms in —SiH₃ is substituted by an alkyl. An alkylarylsilyl refers to a silyl in which one or two of the hydrogen atoms in —SiH₃ are substituted by an alkyl while the remaining one or two hydrogen atoms are substituted by an aryl. An arylheteroarylsilyl refers to a silyl in which one or two of the hydrogen atoms in —SiH₃ are substituted by an aryl while the remaining one or two hydrogen atoms are substituted by a heteroaryl. A heteroarylsilyl refers to a silyl in which at least one of the hydrogen atoms in —SiH₃ is substituted by a heteroaryl. Examples of the arylsilyl include a substituted or unsubstituted monarylsilyl, a substituted or unsubstituted diarylsilyl, and a substituted or unsubstituted triarylsilyl. Such nomenclatures of mono- di-, a and tri- suffixes are true of the alkylsilyl and the heteroarylsilyl.

Here, the aryl in each of the arylsilyl, heteroarylsilyl, and arylheteroarylsilyl may be monocyclic aryl or polycyclic aryl, and the heteroaryl in each of the arylsilyl, the heteroarylsilyl, and the aylheteroarylsilyl may be monocyclic heteroaryl or polycyclic heteroaryl.

Concrete examples of the silyl radicals used in the compounds of the present disclosure include trimethylsilyl, triethylsilyl, triphenylsilyl, trimethoxysilyl, dimethoxyphenylsilyl, diphenylmethylsilyl, diphenylvinlysilyl, methylcyclobutylsilyl, and dimethyl furylsilyl. One or more hydrogen atoms on the silyl may be substituted by the same substituents as on the aryl.

In addition, the term “germyl (or germane)” radical, as used herein, is intended to encompass —GeH₃, an alkylgermyl, an arylgermyl, a heteroarylgermyl, an alkylarylgermyl, an alkylheteroarylgermyl, and an arylheteroarylgermyl, and these germyl radicals are as defined above for the silyl, with a germyl atom (Ge) used, instead of the silicon (Si) atom, for each of the substituents.

Concrete examples of the germyl include trimethylgermyl, triethylgermyl, triphenylgermyl, trimethoxygermyl, dimethoxyphenylgermyl, diphenylmethylgermyl, diphenylvinylgermyl, methylcyclobutylgermyl, and dimethylfurylgermyl. One or more hydrogen atoms on the germyl may be substituted by the same substituents as on the aryl.

As more particular examples accounting for the term “substituted” in the expression “substituted or unsubstituted” used for compounds of [Intermediate A-1], [Intermediate A-2], [Chemical Formula A], and [Chemical Formula B], the compounds may bear as a substituent at least one selected from the group consisting of a deuterium atom, a cyano, a halogen, a hydroxy, a nitro, an alkyl of 1 to 12 carbon atoms, a deuterated alkyl of 1 to 12 carbon atoms, a halogenated alkyl of 1 to 12 carbon atoms, an alkenyl of 2 to 12 carbon atoms, an alkynyl of 2 to 12 carbon atoms, a cycloalkyl of 3 to 12 carbon atoms, a deuterated cycloalkyl of 3 to 12 carbon atoms, a heteroalkyl of 1 to 12 carbon atoms, an aryl of 6 to 18 carbon atoms, a deuterated aryl of 6 to 18 carbon atoms, an arylalkyl of 7 to 18 carbon atoms, a deuterated arylalkyl of 7 to 18 carbon atoms, an alkylaryl of 7 to 18 carbon atoms, a deuterated alkylaryl of 7 to 18 carbon atoms, a heteroaryl of 2 to 18 carbon atoms, a deuterated heteroaryl of 2 to 18 carbon atoms, a heteroarylalkyl of 2 to 18 carbon atoms, a deuterated heteroarylalkyl of 2 to 18 carbon atoms, an alkoxy of 1 to 12 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, an aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 18 carbon atoms, a deuterated aryloxy of 6 to 18 carbon atoms, an arylthionyl of 6 to 18 carbon atoms, and a deuterated arylthionyl of 6 to 18 carbon atoms.

It is meant by the expression “a bond may be formed between R₂ and R₃ and/or between R₄ and R₅ to form an additional mono- or polycyclic aliphatic or aromatic ring” that R₂ and R₃ are each deprived of a hydrogen radical and then connected to each other to form an additional ring, and R₄ and R₅ are also each deprived of a hydrogen radical and then connected to each other to form an additional ring.

What is meant by the expression “any of the substituents R₁ to R₅ in Y₁ may bond to the A₃ ring moiety to form an additional mono- or polycyclic aliphatic or aromatic ring” is that the A₃ ring moiety and R₁ are each deprived of a hydrogen radical and then connected to each other to form an additional ring; the A₃ ring moiety and R₂ or R₃ are each deprived of a hydrogen radical and then connected to each other to form an additional ring; and/or the A₃ ring moiety and R₄ or R₅ are each deprived of a hydrogen radical and then connected to each other to form an additional ring. In this context, the wording “ . . . connected to each other to form an additional ring”, as used herein, means that two substituents are each deprived of a hydrogen radical and then connected to each other to form a ring.

As used herein, the wordings “substituent for X₁” and “substituent for the halogen atom accounting for one of R₁₁ to R₁₄” in the expressions “Z is a substituent for X1 in Intermediate A-2 and is selected from among a hydrogen atom, a deuterium atom, a substituted or unsubstituted alkyl of 1 to 30 carbon atoms . . . ” and “Z is a substituent for the halogen atom accounting for one of R₁₁ to R₁₄ in Intermediate A-4 and is selected from among a hydrogen atom, a deuterium atom, a substituted or unsubstituted alkyl of 1 to 30 carbon atoms . . . ” mean that X₁ or a halogen atom is forced to leave from the aromatic ring bonded thereto and a substituent, instead of the X₁ or halogen atom, is bonded to the leaving site of the aromatic ring.

That is, “Z is a substituent for X₁ in Intermediate A-2 and is a substituted or unsubstituted alkyl of 1 to 30 carbon atoms” implies that X₁ is forced to leave from an aromatic ring moiety bonded thereto in Intermediate A-2 and the substituted or unsubstituted alkyl of 1 to 30 carbon atoms, instead of X₁, is bonded to the leaving site. This meaning is true of expressions analogous to “Z is a substituent for the halogen atom accounting for one of R₁₁ to R₁₄ in Intermediate A-4” throughout the specification.

The ring moieties A₁ to A₃ in [Intermediate A-1], [Intermediate A-2], [Chemical Formula A], and [Chemical Formula B] may be same or different and are each independently a substituted or unsubstituted aromatic ring of 6 to 50 carbon atoms, or a substituted or unsubstituted heteroaromatic ring of 2 to 50 carbon atoms, particularly a substituted or unsubstituted aromatic ring of 6 to 20 carbon atoms or a substituted or unsubstituted heteroaromatic ring of 2 to 20 carbon atoms, and more particularly a substituted or unsubstituted aromatic ring of 6 to 14 carbon atoms or a substituted or unsubstituted heteroaromatic ring of 2 to 14 carbon atoms.

With respect to the technical feature of the present disclosure, the compound represented by [Chemical Formula A] or [Chemical Formula B] is characterized by the structure in which the substituted or unsubstituted aromatic ring of 6 to 50 carbon atoms or the substituted or unsubstituted heteroaromatic ring of 2 to 50 carbon atoms, which is the A₁ ring moiety, is deuterated on at least one carbon atom as a ring member thereof. To this end, the compound represented by [Intermediate A-1] is deuterated in a single step to form the compound represented by [Intermediate A-2], which is then prepared into the compound represented by [Chemical Formula A] or [Chemical Formula B] through an additional multi-step process.

Compared to conventional multi-step manufacturing processes designed to introduce a deuterium atom into fused polycyclic aromatic rings, the method for manufacturing a compound represented by [Chemical Formula A] or [Chemical Formula B] through such new routes according to the present disclosure decreases in process time, improves the final yield of the compound represented by [Chemical Formula A] or [Chemical Formula B], with the resultant increase of an economic benefit, and has the eco-friendly advantage of reducing the use of unnecessary chemicals.

Below, a greater detail will be given of the description for the steps a) and b). In step a), a compound represented by [Intermediate A-1] is deuterated to form a compound represented by [Intermediate A-2], as illustrated in Reaction Scheme A-1, below:

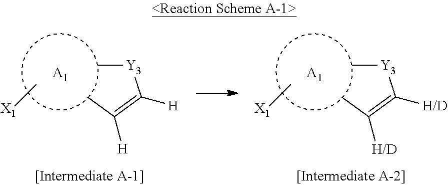

wherein the A₁ ring moiety in [Intermediate A-1] and [Intermediate A-2] is a substituted or unsubstituted aromatic ring of 6 to 50 carbon atoms or a substituted or unsubstituted heteroaromatic ring of 2 to 50 carbon atoms, and X₁ is a halogen element selected from among F, Cl, Br, and I.

With reference to a conventional deuteration reaction of a hydrocarbon bearing an aromatic ring or heteroaromatic ring, as shown in the following Reaction Schemes 1 and 2, when the aromatic ring or heteroaromatic ring does not bear any halogen atom as a substituent, any carbon atom as a ring member in the compound of the aromatic ring or heteroaromatic ring is not prone to undergoing deuteration:

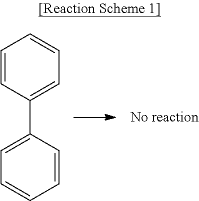 [SMILES: c1ccc(-c2ccccc2)cc1]

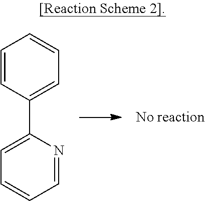 [SMILES: c1ccc(-c2ccccn2)cc1]

In contrast, as illustrated in the following Reaction Schemes 3 and 4, when the aromatic ring or heteroaromatic ring bears a halogen atom as a substituent, the carbon atoms, but for the halogenated carbon atom, as ring members in the compound of the aromatic ring or heteroaromatic ring is prone to undergoing deuteration. For the most part, the deuteration selectively occurs only in the ring moiety bearing a halogen atom.

This reaction might be physicochemically elucidated as follows: a halogen atom in an aromatic ring or a heteroaromatic ring increases the protonation of the hydrogen atoms bonded to the carbon atoms of the aromatic or heteroaromatic ring.

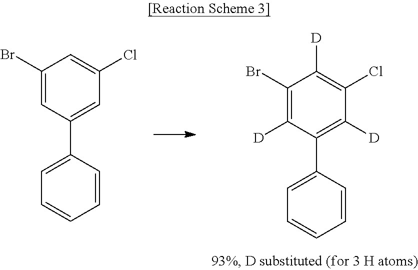 [SMILES: Clc1cc(Br)cc(-c2ccccc2)c1 ; [2H]c1c(Cl)c([2H])c(-c2ccccc2)c([2H])c1Br]

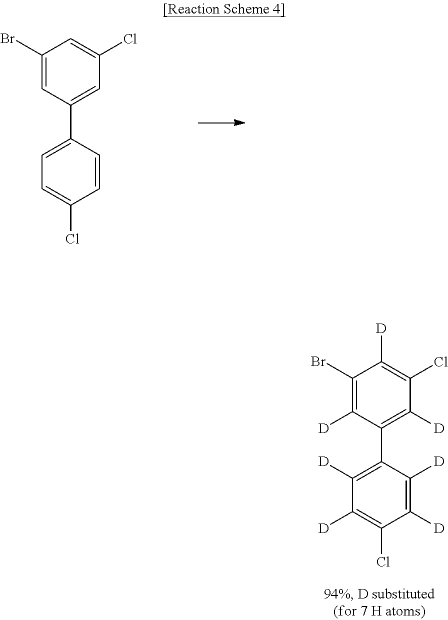 [SMILES: Clc1ccc(-c2cc(Cl)cc(Br)c2)cc1 ; [2H]c1c([2H])c(-c2c([2H])c(Cl)c([2H])c(Br)c2[2H])c([2H])c([2H])c1Cl]

Thus, as explained in the foregoing, step a) in the method for manufacturing a polycyclic compound according to the present disclosure is characterized in that the starting material ([Intermediate A-1]) having a halogen atom introduced into a carbon atom in the aromatic ring or heteroaromatic ring thereof is subjected to deuteration to introduce a deuterium atom into a carbon atom in the halogenated ring (A₁ ring) and the resulting deuterated intermediate ([Intermediate A-2]) is used in the subsequent reaction.

Here, the deuteration reaction in Reaction Scheme A-1 may be carried out by mixing and reacting [Intermediate A-1] with a deuterium atom source at 0° C. to 180° C. for 5 minutes to 24 hours in the presence or absence of an organic solvent to afford [Intermediate A-2].

In this regard, examples of the deuterium atom source may be heavy water (D₂O), a deuterated alcohol of 1 to 5 carbon atoms, and a deuterated carboxylic acid of 2 to 7 carbon atoms, with preference for heavy water (D₂O).

In addition, when the deuteration reaction in Reaction Scheme A-1 is performed in the presence of an organic solvent, the organic solvent may be selected from among an aliphatic hydrocarbon of 5 to 20 carbon atoms, an aromatic hydrocarbon of 6 to 20 carbon atoms, a ketone of 3 to 10 carbon atoms, an alcohol of 1 to 10 carbon atoms, a cyclic or non-cyclic ether of 4 to 10 carbon atoms, and a combination thereof, and preferably may be an aliphatic hydrocarbon of 6 to 10 carbon atoms or an aromatic hydrocarbon of 6 to 10 carbon atoms, for example, toluene, heptane, octane, etc.

Furthermore, in order to enhance the deuteration reaction, a catalyst or an accelerator may be selectively used in Reaction Scheme A-1. For example, at least one selected from among silver carbonate, gamma-alumina, magnesium oxide, calcium oxide, cerium oxide, thorium dioxide, tungsten oxide, 1,2,3-triazolidene, palladium/carbon-, platinum/carbon-, ruthenium-, rhodium-, iridium-based catalysts or accelerators, but with no limitations thereto.

Regarding the deuteration reaction according to Reaction Scheme A-1, the halogen atom bonded to the aromatic ring A₁ in the compound represented by [Intermediate A-1] induces the protonation of the hydrogen atoms bonded to the aromatic ring, which leads to the substitution of a deuterium atom for at least one of the protonation-prone hydrogen atoms. In this regard, the two hydrogen atoms bonded respectively to the ethenyl carbons in the Y₃-bearing 5-membered ring fused to the A₁ ring may be replaced by a deuterium atom, depending on the reaction conditions or types of Y₃. However, as will be described hereinafter, it is not important to replace deuterium atoms for the two hydrogen atoms on the respective carbon atoms of the ethenyl moiety in the 5-membered ring because the ethenyl atoms are finally fused into cyclization in a subsequent process.

As illustrated in Reaction Scheme A-1, the introduction of a deuterium atom into the “halogen-substituted A₁ ring” or “halogenated A₁ ring” through the deuteration reaction according to the present disclosure is a single-step reaction that allows for the substitution of a deuterium atom for a hydrogen atom bonded to a halogen-substituted ring. For comparison, a deuterium atom is introduced into the ‘A₁ ring’-‘Y₃-bearing 5-membered ring’ system according to a conventional technique. For example, when the A₁ ring is a benzene ring and Y₃ is sulfur, as illustrated in the following Reference Reaction Scheme C-1, a deuterated 5-bromobenzothiophene is prepared from the starting material perdeuterated bromobenzene through a total of four synthesis processes, with an overall reaction yield of as low as of about 27% for the final product (deuterated 5-bromobenzothiophene). However, the single-step reaction according to the present disclosure guarantees a yield of 90% or higher.

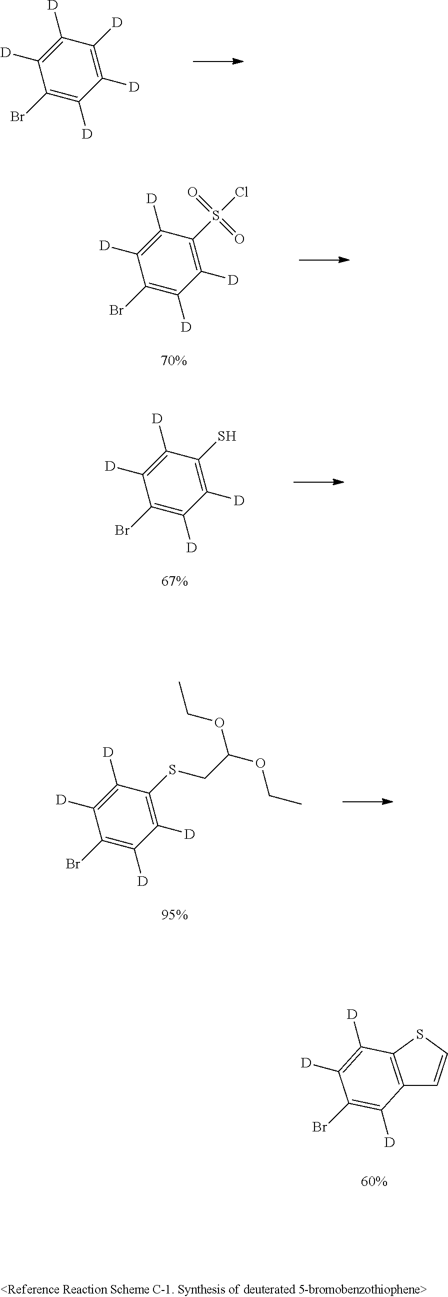 [SMILES: [2H]c1c([2H])c([2H])c(Br)c([2H])c1[2H] ; [2H]c1c([2H])c(S(=O)(=O)Cl)c([2H])c([2H])c1Br ; [2H]c1c([2H])c(Br)c([2H])c([2H])c1S ; [2H]c1c([2H])c(SCC(OCC)OCC)c([2H])c([2H])c1Br ; [2H]c1c(Br)c([2H])c2ccsc2c1[2H]]

In step b) according to the present disclosure, [Intermediate A-2](fused compound bearing deuterated A₁ ring) obtained in step a) is used as a starting material and prepared into a compound represented by [Chemical Formula A] or [Chemical Formula B] through multiple subsequent steps.

Here, step b) may be a multi-step process leading to the preparation of the final compound through various routes according to the design of synthesis scheme. Main processes for the synthesis of the compound represented by Chemical Formula A, as shown in Reaction Scheme B, below, may include the steps of: (b1 reaction) subjecting a deuterated compound represented by [Intermediate A-2] to a coupling reaction to leave X₁ from the A₁ ring and introduce a substituent Z into the same site to synthesize a Z-substituted compound (Intermediate A-2-1); (b2 reaction) reacting a compound bearing Y₁ and A₃ with Intermediate A-2-1 to prepare Intermediate A-2-2; (b3 reaction) reacting a compound bearing Y₂ and A₂ with Intermediate A-2-2 to prepare Intermediate A-2-3; and (b4 reaction) introducing a boron atom into Intermediate A-2-3, but is not limited thereto.

[Reaction Scheme B]

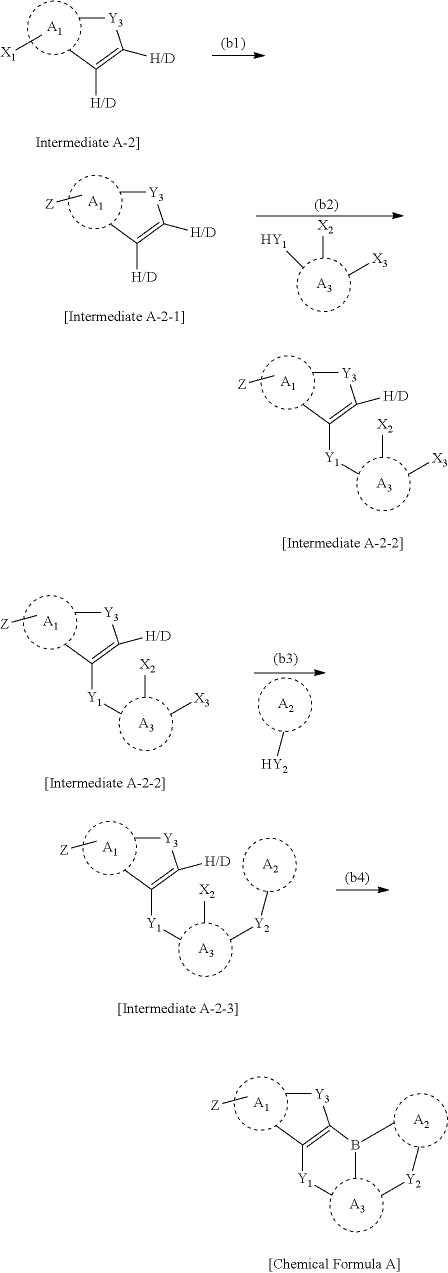

The (b2) reaction accounts for coupling Intermediate A-2-1 to the A₃ ring moiety, the (b3) reaction for coupling Intermediate A-2-2 to the A₂ ring moiety, and the (b4) reaction for introducing a boron atom into Intermediate A-2-3 to prepare the final dopant compound.

The (b1) reaction in step b) is adapted to leave X₁ from [Intermediate A-2] and bond Z to the same leaving site to form [Intermediate A-2-1], as illustrated in the following [Reaction Scheme A-2]:

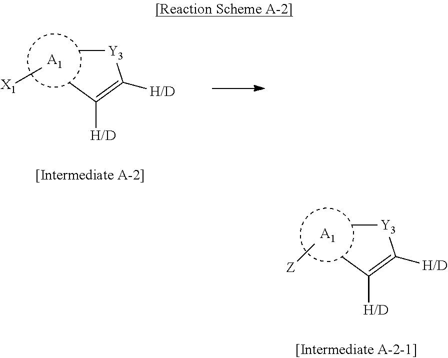

wherein,

X₁ is a halogen element selected from among F, Cl, Br, and I,

Y₃ is any one selected from among N—R₁, CR₂R₃, O, S, Se, and SiR₄R₅,

R₁ to R₅, which are same or different, are each independently selected from among a hydrogen atom, a deuterium atom, a substituted or unsubstituted alkyl of 1 to 30 carbon atoms, a substituted or unsubstituted alkenyl of 2 to 24 carbon atoms, a substituted or unsubstituted alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, a halogen,

Z is a substituent for X₁ of [Intermediate A-2], and is selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, and a halogen atom, and

the A₁ ring and Y₃ are each as defined above,

wherein at least one of the hydrogen atoms bonded to the aromatic carbon atoms of the A₁ ring is substituted by a deuterium atom.

In this regard, the (b1) reaction for preparing the compound represented by Intermediate A-2-1 takes advantage of the Suzuki-Miyaura cross coupling reaction in which Z in a boron compound is introduced into the A₁ ring while leaving the halogen element (X₁) from the A₁ ring. This coupling reaction is generally used to synthesize an aryl-aryl compound from an aryl halide and an aryl boron compound.

Hence, after the (b1) reaction, the compound represented by Intermediate A-2-1 is a deuterated, fused ring in which the A₁ ring bears no X₁(halogen), and serves as a staring material for a subsequent reaction.

The cross-coupling reaction between the compound represented by Intermediate A-2 and a boron compound bearing Z may be performed in the presence of a palladium catalyst and a base in an organic solvent.

The organic solvents useful for Reaction Scheme A-1 are available for the cross-coupling reaction. Examples of the palladium catalyst include tetrakis(triphenylphosphine)palladium, tris(dibenzylideneacetone)dipalladium, palladium (II) acetate, palladium (II) chloride, bis(triphenylphosphine)palladium chloride, palladium (II) chloride dimer, and bis(acetonitrile)palladium chloride, and the base may be exemplified by potassium carbonate, cesium carbonate, sodium acetate, barium hydroxide, cesium fluoride, and potassium acetate, but with no limitations thereto.

In addition, the substituent Z useful for the coupling reaction in the (b1) reaction may be preferably selected from among a deuterium-substituted or unsubstituted alkyl of 1 to 10 carbon atoms, a deuterium-substituted or unsubstituted aryl 6 to 18 carbon atoms, a deuterium-substituted or unsubstituted cycloalkyl of 3 to 10 carbon atoms, a deuterium-substituted or unsubstituted heteroaryl of 2 to 18 carbon atoms, a deuterium-substituted or unsubstituted, aromatic ring-fused cycloalkyl of 8 to 18 carbon atoms, and a deuterium-substituted or unsubstituted, aliphatic ring-fused aryl of 8 to 18 carbon atoms.

In addition, in the (b2) reaction of step b), a compound bearing Y₁ and a A₃ ring moiety is prepared and reacted with Intermediate A-2-1 to prepare Intermediate A-2-2. In this regard, in order to combine Intermediate A-2-1 with the compound bearing Y₁ and A₃

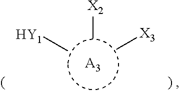

one of the hydrogen atoms bonded to the ethenyl carbons in Intermediate A-2-1 (particularly the hydrogen atom at the beta position to Y₃, that is, the hydrogen atom on the ethenyl carbon atom not linked directly to Y₃) is converted into a halogen atom which, in turn, serves as a leaving group in the reaction to bond Y₁ to the ethenyl carbon. For this, Y₁ may be any one selected from among N—R₁, CR₂R₃, O, S, Se, and SiR₄R₅, preferably from among N—R₁, O, and S, and more preferably N—R₁.

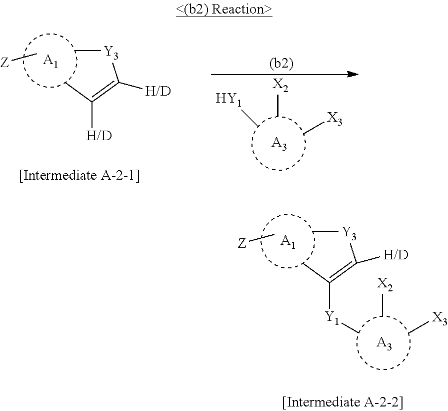

wherein, X₂ and X₃, which may be same or different, are each independently any one selected from among a hydrogen atom, a deuterium atom, and a halogen atom. X₂ is removed as a boron atom is introduced in a subsequent reaction while X₃ is removed in a subsequent reaction in which the Intermediate A-2-2 reacts with a compound bearing Y₂ and A₂ to bond Y₂ to the A₃ ring moiety.

The (b2) reaction is a coupling reaction between a nitrogen atom, a carbon atom, or an oxygen atom in Y₁ and a halogen atom substituted for the hydrogen atom bonded to the ethenyl carbon in Intermediate A-2-1 and may be conducted in the presence of a palladium catalyst and a base in an organic solvent. The organic solvents useful for Reaction Scheme A-1 are available for this coupling reaction. Examples of the palladium catalyst include bis(tri-tert-butyl phosphine)palladium, tris (dibenzylideneacetone) dipalladium, palladium(II) acetate, palladium(II) chloride, bis(triphenylphosphine)palladium chloride, palladium (II) chloride dimer, and bis(acetonitrile)palladium chloride, and the base may be exemplified by sodium tert-butoxide, sodium ethoxide, potassium carbonate, cesium carbonate, sodium acetate, barium hydroxide, cesium fluoride, and potassium acetate, but with no limitations thereto.

In addition, the (b3) reaction in step b) is adapted to react a compound bearing Y₂ and A₂

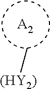

with Intermediate A-2-2 to prepare Intermediate A-2-3. In order to couple Intermediate A-2-2 with the compound bearing Y₂ and A₂, Y₂, instead of X₃, is bonded to A₃ ring of Intermediate A-2-2. For this, Y₁ may be any one selected from among N—R₁, CR₂R₃, O, S, Se, and SiR₄R₅, preferably from among N—R₁, O, and S, and more preferably N—R₁. X₃ may be any one selected from among a hydrogen atom, a deuterium atom, and a halogen atom and preferably a halogen atom.

<(b3) Reaction>

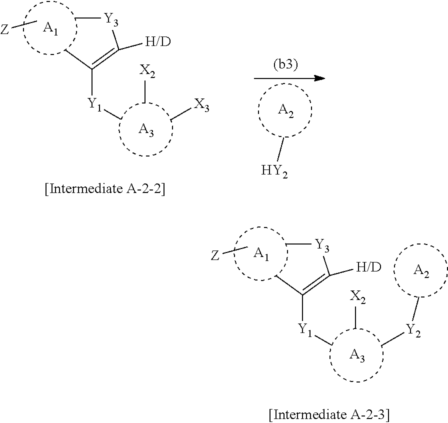

Here, X₂ is removed as a boron atom is introduced.

The (b3) reaction is a coupling reaction between a nitrogen atom, a carbon atom, or an oxygen atom in Y₂ and X₃ in Intermediate A-2-2 and may be conducted in the presence of a palladium catalyst and a base in an organic solvent. The organic solvents useful for Reaction Scheme A-1 are available for this coupling reaction. Examples of the palladium catalyst include bis(tri-tert-butyl phosphine)palladium, tris (dibenzylideneacetone) dipalladium, palladium(II) acetate, palladium (II) chloride, bis(triphenylphosphine)palladium chloride, palladium (II) chloride dimer, and bis(acetonitrile)palladium chloride, and the base may be exemplified by sodium tert-butoxide, sodium ethoxide, potassium carbonate, cesium carbonate, sodium acetate, barium hydroxide, cesium fluoride, and potassium acetate, but with no limitations thereto.

The (b4) reaction in step b) is the final reaction in step b) and accounts for the introduction of boron into Intermediate A-2-3.

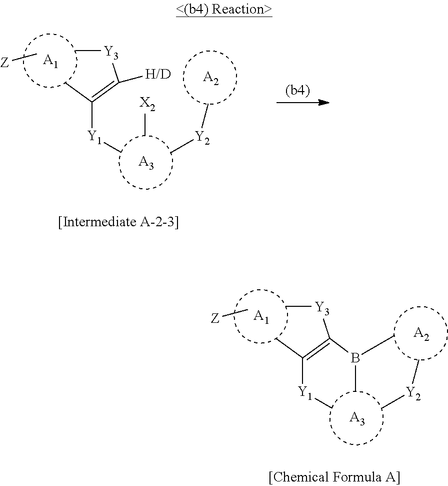

With respect to the introduction of a boron atom as a central atom in a compound bearing multiple aromatic rings, reference may be made to Korean Patent No. 10-2016-0119683 A (Oct. 14, 2016), which discloses two reaction routes as illustrated in the following Reference Reaction Schemes C-2 and C-3.

In the first route, as shown in Reference Reaction Scheme C-2, the Intermediate in which hydrogen atom (H) is bonded to the aromatic ring a is reacted with boron halide or boron alkoxide to synthesize a boron dopant compound:

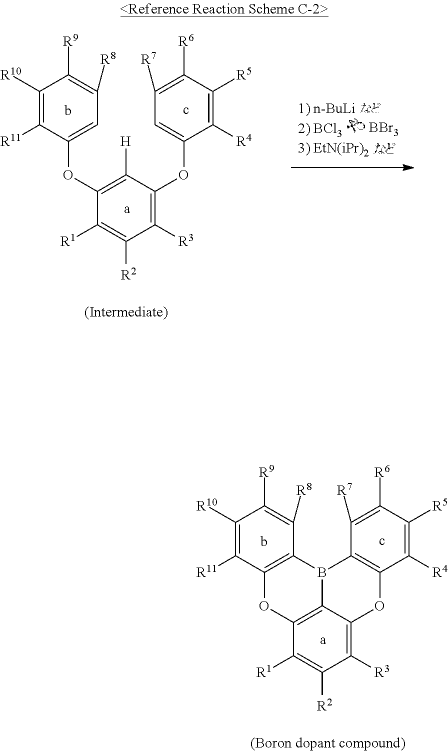

In the second route, as shown in Reference Reaction Scheme C-3, the Intermediate in which halogen atom (ex: Br) is bonded to the aromatic ring a is reacted with boron halide or boron alkoxide to synthesize a boron dopant compound.

In the present disclosure, the two routes may be employed to synthesize a boron dopant compound useful in an organic light-emitting diode.

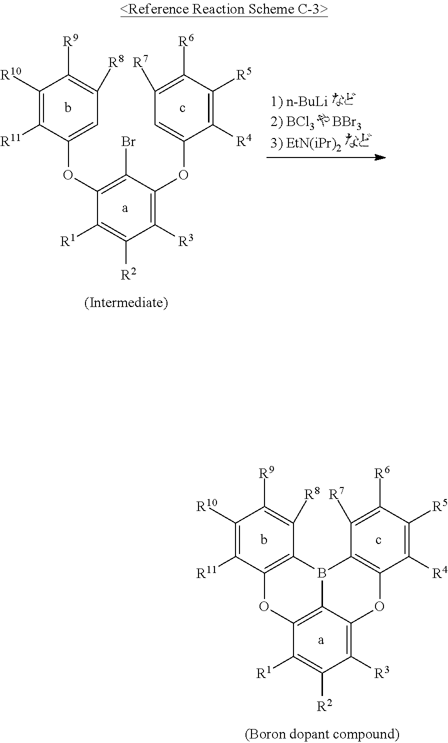

The (b4) reaction may be conducted in an organic solvent. The organic solvents useful for Reaction Scheme A-1 are available for this coupling reaction.

Also, the reaction may be carried out in the presence of a base. Examples of the base include, but are not limited to, tert-butyl lithium, N-butyl lithium, methyl lithium, methyl magnesium bromide, and lithium dimethyl cooperate. As a boron precursor used in the reaction, boron halide may be available and may be preferably exemplified by boron tribromide, boron trichloride, boron triiodide, boron trifluoride, etc., but with no limitations thereto.

The A₁ ring in [Intermediate A-1], [Intermediate A-2], [Chemical Formula A], and [Chemical Formula B] according to the present disclosure may be preferably a substituted or unsubstituted benzene ring.

In greater detail, the present disclosure provides a method for manufacturing a compound represented by [Chemical Formula A-1] or [Chemical Formula B-1], the method including the steps of: (a) deuterating a compound represented by [Intermediate A-3] to prepare a compound represented by [Intermediate A-4]; and (b) preparing a compound represented by [Chemical Formula A-1] or [Chemical Formula B-1] from the compound represented by [Intermediate A-4]:

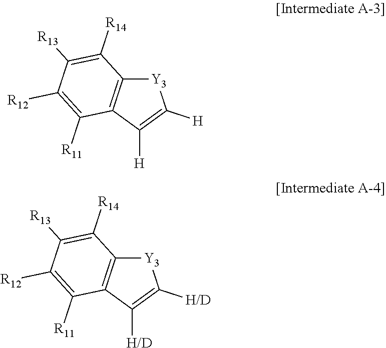

wherein,

R₁₁ to R₁₄, which may be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, a deuterium-substituted or unsubstituted arylthionyl of 6 to 24 carbon atoms, with a proviso that one of the substituents R₁₁ to R₁₄ is a halogen atom selected from among F, Cl, Br, and I,

Y₃ is any one selected from among N—R₁, CR₂R₃, O, S, Se, and SiR₄R₅, as defined above,

Wherein at least one of the three, non-halogen substituents among R₁₁ to R₁₄ in [Intermediate A-4] is a deuterium atom, and

H/D means that a hydrogen atom or a deuterium atom bonds to a carbon atom;

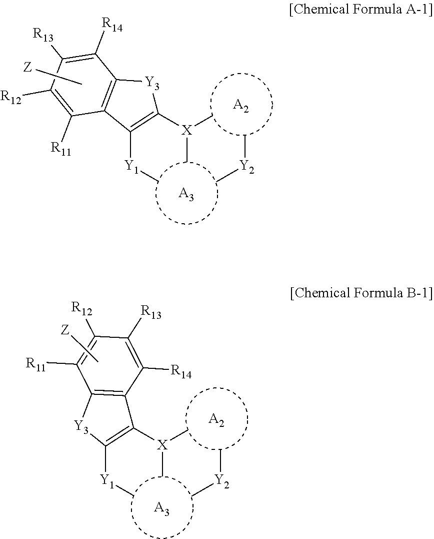

wherein,

R₁₁ to R₁₄, which may be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms,

Z is a substituent for the halogen atom accounting for one of R₁₁ to R₁₄ in [Intermediate A-4], and is selected from among a hydrogen atom, a deuterium atom, a deuterium-substituted or unsubstituted alkyl of 1 to 30 carbon atoms, a deuterium-substituted or unsubstituted aryl of 6 to 50 carbon atoms, a deuterium-substituted or unsubstituted cycloalkyl of 3 to 30 carbon atoms, a deuterium-substituted or unsubstituted heteroaryl of 2 to 50 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, and a halogen atom, and

wherein one of R₁₁ to R₁₄ is Z and at least one of the three substituents, which are not Z, among R₁₁ to R₁₄ is a deuterium atom, and

the A₂ ring moiety, the A₃ ring moiety, X, and Y₁ to Y₃ are each as defined above.

According to the present disclosure, a deuterium atom can be thus effectively introduced into the benzene ring moiety having the substituents R₁₁ to R₁₄ bonded thereto in the fused heteroaromatic ring of the compound represented by [Chemical Formula A-1] or [Chemical Formula B-1]. Thus, through the step of preparing a compound represented by Intermediate A-4 by deuterating a compound represented by Intermediate A-3 in a single-step manner, at least one of the substituents R₁₁ to R₁₄ in the benzene ring moiety of the fused, heteroaromatic ring structure is substituted by a deuterium atom, whereby a compound represented by [Chemical Formula A-1] or [Chemical Formula B-1] bearing a deuterium atom in the benzene ring moiety of the fused, heteroaromatic ring structure can be synthesized in subsequent steps.

In the method for manufacturing a polycyclic compound represented by [Chemical Formula A-1] or [Chemical Formula B-1] according to some particular embodiments, step b) includes leaving a halogen atom responsible for any one of the substituents R₁₁ to R₁₄ from [Intermediate A-4] and bonding Z to [Intermediate A-4] to form [Intermediate A-4-1], as illustrated in [Reaction Scheme A-4], below:

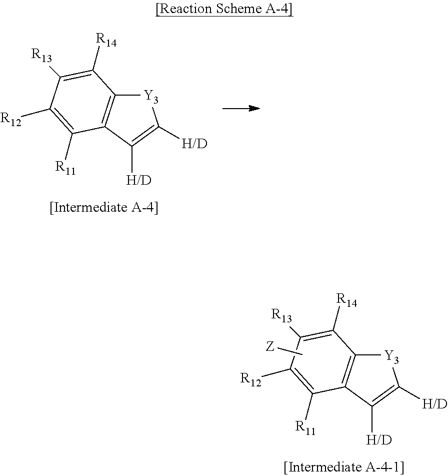

wherein,

Y₃ is as defined in Intermediate A-4,

R₁₁ to R₁₄ in [Intermediate A-4], which may be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms, with a proviso that one of the substituents R₁₁ to R₁₄ is a halogen atom selected from among F, Cl, Br, and I,

wherein at least one of the three, non-halogen substituents among R₁₁ to R₁₄ is a deuterium atom,

R₁₁ to R₁₄ in [Intermediate A-4-1], which may be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms,

Z is a substituent for the halogen atom accounting for one of R₁₁ to R₁₄ in [Intermediate A-4], and is selected from among a hydrogen atom, a deuterium atom, a deuterium-substituted or unsubstituted alkyl of 1 to 30 carbon atoms, a deuterium-substituted or unsubstituted aryl of 6 to 50 carbon atoms, a deuterium-substituted or unsubstituted cycloalkyl of 3 to 30 carbon atoms, a deuterium-substituted or unsubstituted heteroaryl of 2 to 50 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, and a deuterium-substituted or unsubstituted germyl of 0 to 30 carbon atoms, and a halogen, and

wherein one of R₁₁ to R₁₄ is Z and at least one of the three substituents, which are not Z, among R₁₁ to R₁₄ is a deuterium atom,

That is, [Reaction Scheme A-4] accounts for [Reaction Scheme A-2] in which the A₁ ring moiety is limited to a benzene ring. Thus, [Intermediate A-4-1] obtained through [Reaction Scheme A-4] corresponds to [Intermediate A-2-1] in Reaction Scheme B and thus can be subjected to the same subsequent reactions ((b2) to (b4) reaction), whereby the compound represented by [Chemical Formula A-1] or [Chemical Formula B-1] can be finally provided.

In addition, all the hydrogen atoms bonded to the aromatic carbon atoms of the A₁ ring moiety in [Chemical Formula A] and [Chemical Formula B] may be substituted by deuterium atoms.

Furthermore, three of the substituents R₁₁ to R₁₄ in [Chemical Formula A-1] and [Chemical Formula B-1] according to the present disclosure may each be a deuterium atom if they are not Z.

The substituent Z in [Chemical Formula A], [Chemical Formula B], [Chemical Formula A-1], and [Chemical Formula B-1] according to the present disclosure may be a substituted or unsubstituted aryl of 6 to carbon atoms and preferably a deuterium-substituted or unsubstituted aryl of 6 to 20 carbon atoms.

At least one of the substituents Y₁ and Y₂ in [Chemical Formula A], [Chemical Formula B], [Chemical Formula A-1], and [Chemical Formula B-1] according to the present disclosure may be NR₁, wherein R₁ may be any one selected from among a hydrogen atom, a deuterium atom, a substituted or unsubstituted alkyl of 1 to 30 carbon atoms, an alkenyl of 2 to 24 carbon atoms, an alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, preferably a substituted or unsubstituted aryl of 6 to 50 carbon atoms or a substituted or unsubstituted heteroaryl of 2 to 50 carbon atoms, and more preferably a substituted or unsubstituted aryl of 6 to 20 carbon atoms or a substituted or unsubstituted heteroaryl of 2 to 20 carbon atoms.

The linkers Y₁ and Y₂ in [Chemical Formula A], [Chemical Formula B], [Chemical Formula A-1], and [Chemical Formula B-1] according to the present disclosure may both be NR₁.

In addition, the linkers Y₁ and Y₂ in [Chemical Formula A] and [Chemical Formula B] may be same or different and at least one of them may be the linker represented by the following [Structural Formula A]:

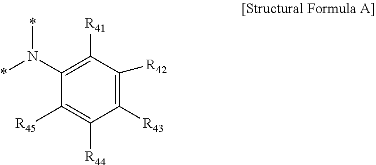

wherein

“-*” denotes a bonding site at which the N atom is bonded to the ethenyl carbon atom connected to Y₁, an aromatic carbon atom in A₂ ring moiety, or an aromatic carbon atom in A₃ ring moiety; and

R₄₁ to R₄₅, which may be same or different, are each independently any one selected from among a deuterium atom, a cyano, a halogen, an alkyl of 1 to 24 carbon atoms, a deuterated alkyl of 1 to 24 carbon atoms, a cycloalkyl of 3 to 24 carbon atoms, a deuterated cycloalkyl of 3 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, an aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, and an arylthionyl of 6 to 24 carbon atoms, and R₄₁ and R₄₅ may each independently be bonded to the A₁, A₂, or A₃ ring moiety to form an additional mono- or polycyclic aliphatic or aromatic ring.

Meanwhile, the expression “R₄₁ and R₄₅ may each independently be bonded to the A₁, A₂, or A₃ ring moiety to form an additional mono- or polycyclic aliphatic or aromatic ring” means that the substituent R₄₁ or R₄₅ and the A₁, A₂, or A₃ ring moiety are each deprived of a hydrogen radical and connected to each other to form an additional ring, as described for the foregoing bond between R₂ and R₃, between R₄ and R₅, etc., and the meaning is true of the expression “to form an additional ring” that will be given herein.

In [Chemical Formula A] and [Chemical Formula B], the linker Y₁ may be an oxygen atom (0) or a sulfur atom (S). In [Chemical Formula A] and [Chemical Formula B], the central atom (X) may be particularly a boron atom (B).

Furthermore, in [Chemical Formula A], [Chemical Formula B], [Chemical Formula A-1], and [Chemical Formula B-1] according to the present disclosure, at least one of the hydrogen atoms bonded to the aromatic carbon atoms in the A₂ ring may be substituted by a deuterium atom or at least one of the hydrogen atoms bonded to the aromatic carbon atoms in the A₃ ring may be substituted by a deuterium atom. In this regard, the hydrogen atoms bonded to the aromatic carbon atoms in the A₃ ring moiety may all be preferably substituted by a deuterium atom or the hydrogen atoms bonded to the aromatic carbon atoms in the A₂ ring moiety may all be preferably substituted by a deuterium atom.

With the structure in which at least one of the hydrogen atoms bonded to the aromatic carbon atoms of the A₂ or A₃ ring moiety in [Chemical Formula A], [Chemical Formula B], [Chemical Formula A-1], and [Chemical Formula B-1], the polycyclic ring compound represented by any one of [Chemical Formula A], [Chemical Formula B], [Chemical Formula A-1], and [Chemical Formula B-1] can be used as a dopant material in an organic light-emitting diode and thus can improve longevity and stability in the organic light-emitting diode.

As described in the foregoing, the substitution of a deuterium atom for a hydrogen atom bonded to an aromatic carbon atom in the A₂ or A₃ ring moiety may be easily achieved by introducing a halogen atom into the A₂ or A₃ ring moiety before deuteration, and the compound having at least one deuterium atom on the A₂ or A₃ ring can be prepared into a boron compound through the subsequent reactions.

In some particular embodiments of the present disclosure, the A₁ to A₃ rings in the compound represented by [Chemical Formula A] or [Chemical Formula B] may be same or different and are each independently a substituted or unsubstituted aromatic ring of 6 to 50 carbon atoms. Concretely, the ring may be any one selected from among a benzene ring, a naphthalene ring, a biphenyl ring, a terphenyl ring, an anthracene ring, a phenanthrene ring, an indene ring, a fluorene ring, a pyrene ring, a perylene ring, a chrysene ring, a naphthacene ring, a fluoranthene ring, and a pentacene ring.

In addition, when the aromatic rings of A₁ to A₃ are same or different and are each independently a substituted or unsubstituted aromatic ring of 6 to 50 carbon atoms, the aromatic rings of A₁ and A₂ in Chemical Formulas A and B may each be any one selected from among [Structural Formula 10] to [Structural Formula 21], below:

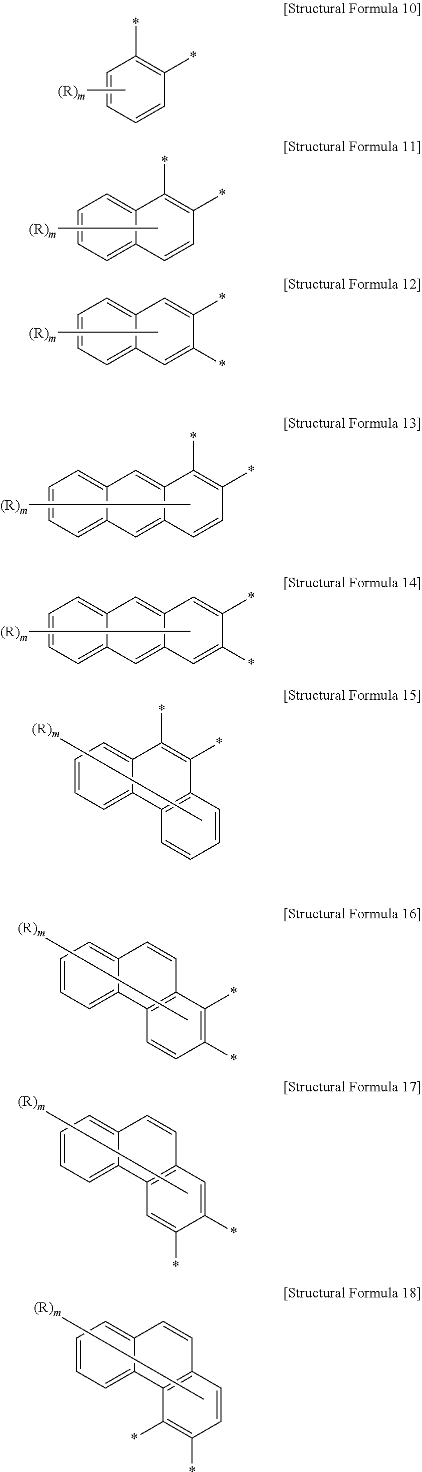

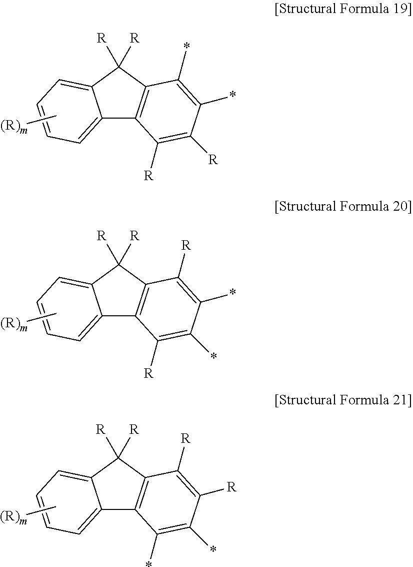

wherein “-*” denotes a bonding site at which the carbon member of the A₁ ring is bonded to the substituent Y₃ or a carbon member of the 5-membered ring bearing Y₃, or the carbon member of the A₂ ring is bonded to X or Y₂,

R's, which may be same or different, are each independently any one selected from a hydrogen atom, a deuterium atom, a substituted or unsubstituted alkyl of 1 to 30 carbon atoms, an alkenyl of 2 to 24 carbon atoms, an alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, and

m is an integer of 1 to 8 wherein when m is 2 or greater or when two or more R's exist, the individual R's may be same or different.

In addition, when the A₁ to A₃ ring moieties, which may be same or different, are each independently a substituted or unsubstituted aromatic ring of 6 to 50 carbon atoms, the aromatic ring of A₃ in Chemical Formulas A and B may be a ring represented by the following Structural Formula B:

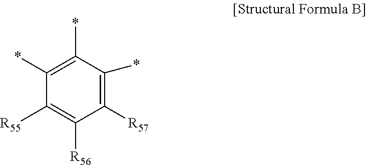

wherein,

“-*” denotes a bonding site at which the corresponding aromatic carbon members of the A₃ ring are bonded to Y₁, X, and Y₂, respectively; and

R₅₅ to R₅₇, which may be same or different, are each independently any one selected from among a hydrogen atom, a deuterium atom, a substituted or unsubstituted alkyl of 1 to 30 carbon atoms, a substituted or unsubstituted alkenyl of 2 to 24 carbon atoms, a substituted or unsubstituted alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 5 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, and

R₅₅ to R₅₇ may each be linked to an adjacent substituent to form an additional mono- or polycyclic aliphatic or aromatic ring.

Alternatively, when the A₁ to A₃ ring moieties in the compounds represented by [Chemical Formula A] or [Chemical Formula B] are each a substituted or unsubstituted heteroaromatic ring of 2 to 50 carbon atoms, the corresponding heteroaromatic rings may be same or different and may each be independently any one selected from [Structural Formula 31] to [Structural Formula 40]:

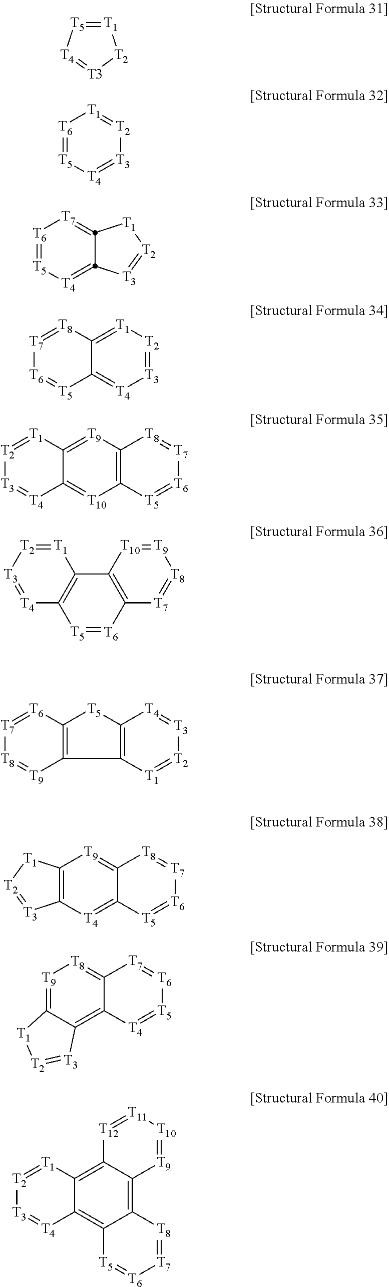

wherein,

T₁ to T₁₂, which may be same or difference, are each independently any one selected from among C(R₆₁), C(R₆₂)(R₆₃), N, N(R₆₄), O, S, Se, Te, Si(R₆₅)(R₆₆), and Ge (R₆₇)(R₆₈), with the exclusion of the case where all of the T's as ring members in each aromatic ring moiety are carbon atoms, wherein R₆₁ to R₆₈ are each as defined for R₁ above.

Here, the compound of [Structural Formula 33] may include the compound represented by the following Structural Formula 33-1 due to a resonance structure based on delocalized electrons:

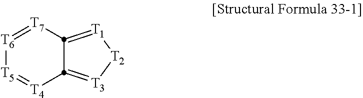

wherein,

T₁ to T₇ are as defined in [Structural Formula 31] to [Structural Formula 40].

Furthermore, the compounds of [Structural Formula 31] to [Structural Formula 40] may each be any one selected from heterocyclic structures of the following [Structural Formula 50]:

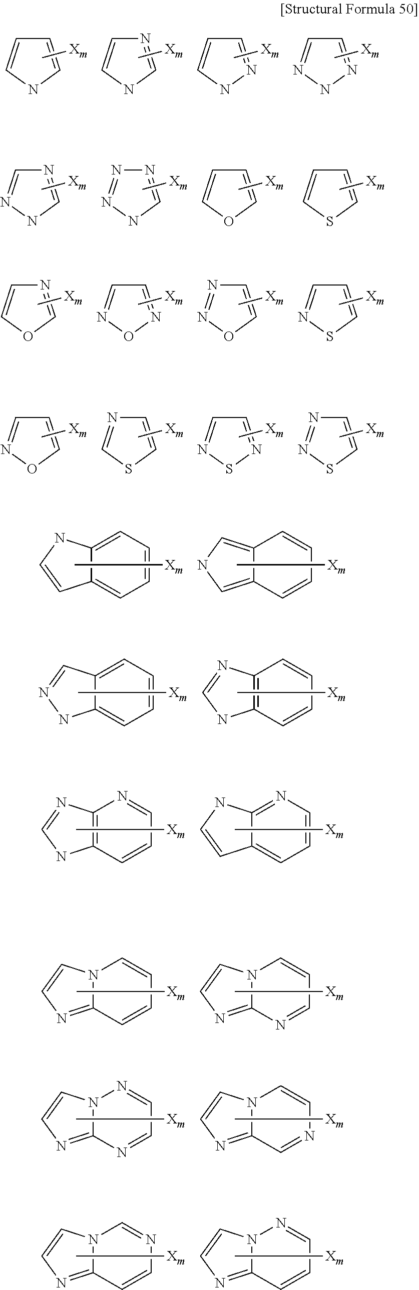

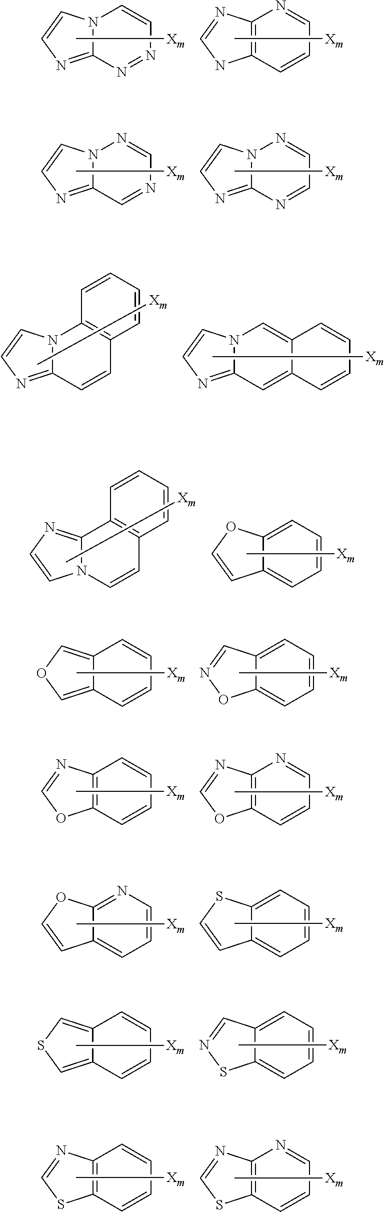

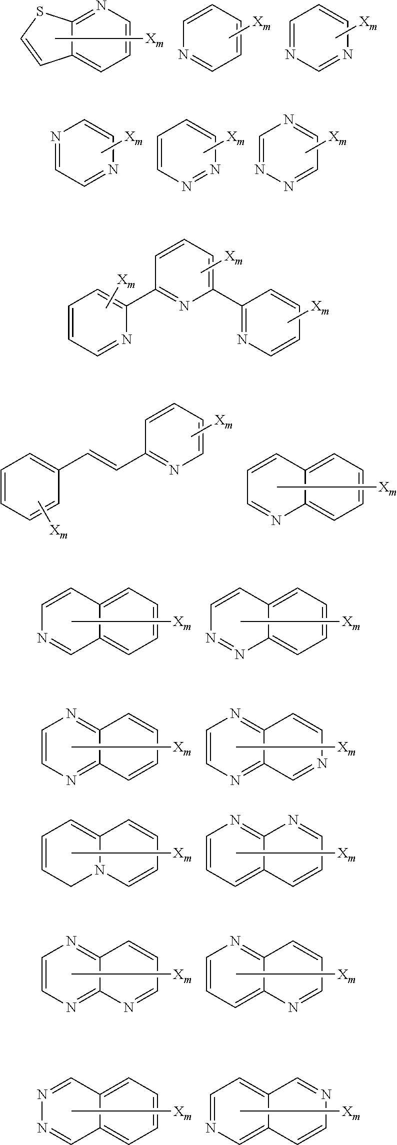

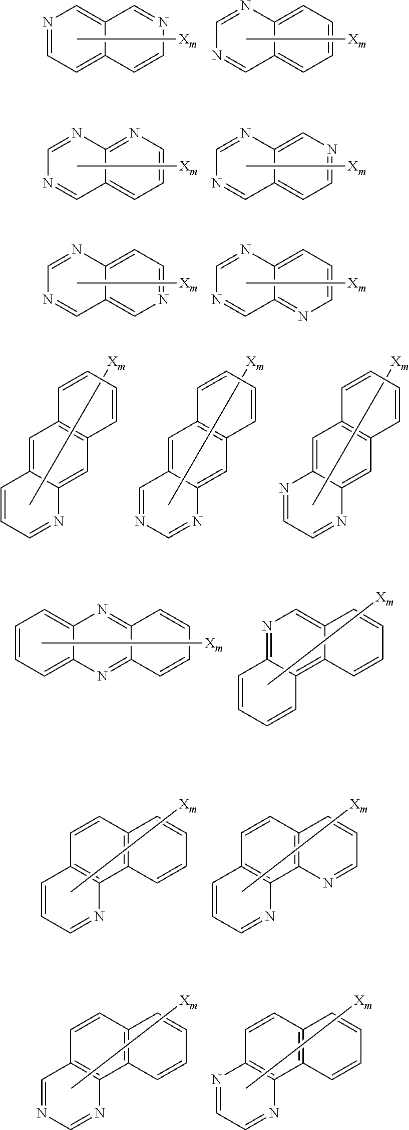

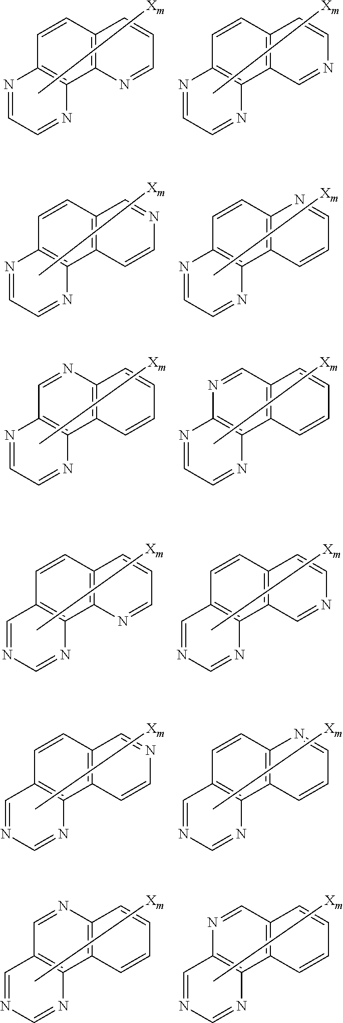

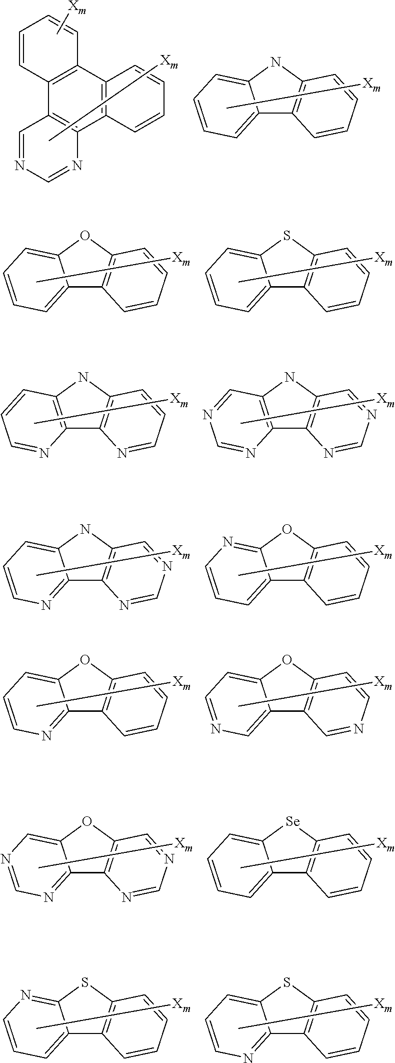

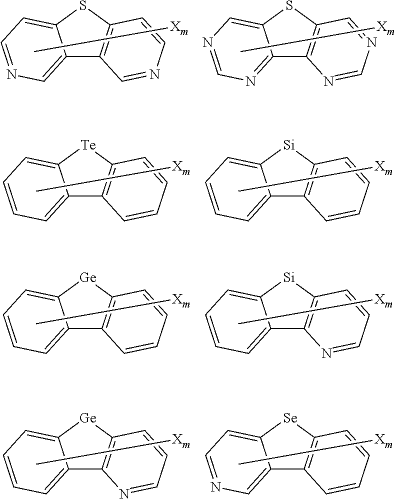

wherein,

the substituent X is as defined for R₁ above, and

m is an integer of 1 to 11 wherein when m is 2 or greater, the corresponding multiple X's are same or different.

In [Chemical Formula A] and [Chemical Formula B] of the present disclosure, the aromatic hydrocarbon ring of 6 to 50 carbon atoms or the heteroaromatic ring of 2 to 50 carbon atoms of at least one of the A₁ to A₃ ring moieties may be bonded to an aryl amino radical and preferably to one or two aryl amino radicals, each represented by the following Structural Formula F:

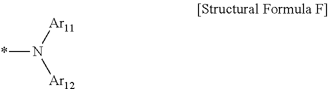

wherein,

“-*” denotes a bonding site participating in forming a bond to a carbon aromatic ring member of any one of A₁ to A₃, and

Ar₁₁ and Ar₁₂, which may be same or different, are each independently a substituted or unsubstituted aryl of 6 to 18 carbon atoms or a substituted or unsubstituted heteroaryl of 3 to 18 carbon atoms, and preferably a substituted or unsubstituted aryl of 6 to 12 carbon atoms or a substituted or unsubstituted heteroaryl of 3 to 12 carbon atoms, and may be linked to each other to form a ring.

As described hereinbefore, the polycyclic ring compounds represented by [Chemical Formula A] and [Chemical Formula B], prepared from the intermediated compound represented by [Intermediate A-2], or the polycyclic ring compounds represented by [Chemical Formula A-1] and [Chemical Formula B-1], prepared from the intermediate compound represented by [Intermediate A-4], can be used as materials for organic light-emitting diodes.

For an organic light-emitting diode including: a first electrode; a second electrode facing the first electrode; and a light-emitting layer disposed between the first and the second electrode, the polycyclic ring compounds represented by [Chemical Formula A], [Chemical Formula B], [Chemical Formula A-1], and [Chemical Formula B-1] may be used as a dopant, together with a host compound, in the light-emitting layer.

In this context, the organic light-emitting diode may include at least one of a hole injection layer, a hole transport layer, a functional layer capable of both hole injection and hole transport, an electron transport layer, and an electron injection layer, in addition to the light-emitting layer, and preferably may include an anode, a hole injection layer, a hole transport layer, a light-emitting layer, an electron transport layer, an electron injection layer, and a cathode, and other additional layers as needed.

In the light-emitting layer, a host material may be employed, together with the dopant material. When the light-emitting layer contains a host and a dopant, the content of the dopant in the light-emitting layer may range from about 0.01 to 20 parts by weight, based on 100 parts by weight of the host, but is not limited thereto.

A better understanding of the present disclosure may be obtained through the following examples which are set forth to illustrate, but are not to be construed as limiting the present disclosure.

### EXAMPLES

### Synthesis Example 1: Synthesis of [BD-1]

### Synthesis Example 1-1: Synthesis of A-1

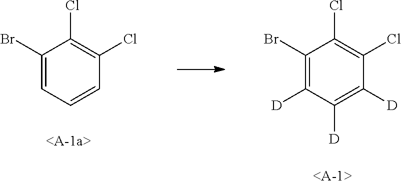 [SMILES: Clc1cccc(Br)c1Cl ; [2H]c1c([2H])c(Cl)c(Cl)c(Br)c1[2H]]

In a reactor, <A-1a> (40 g), silver carbonate (9.77 g), cyclohexyldiphenylphosphine (19 g), potassium carbonate (24.5 g), heavy water (64 mL), and toluene (18 mL) were stirred together for 6 hours under reflux. The mixture was cooled to room temperature and subjected into layer separation with toluene, and the organic layer was collected and concentrated in a vacuum. Purification by silica gel column chromatography afforded <A-1>. (36.2 g, 89.3%)

### Synthesis Example 1-2 Synthesis of A-2

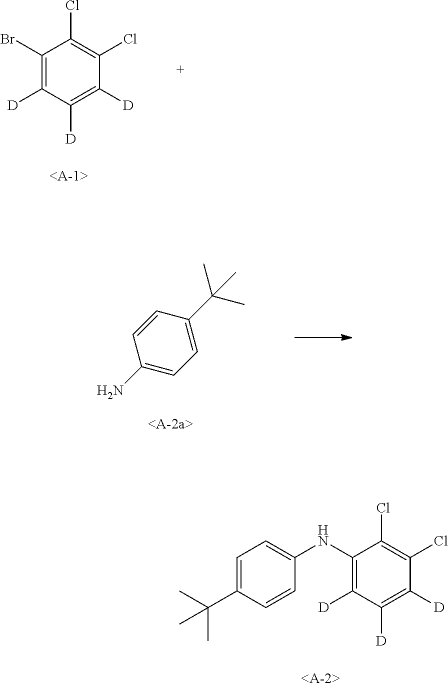 [SMILES: [2H]c1c([2H])c(Cl)c(Cl)c(Br)c1[2H] ; CC(C)(C)c1ccc(N)cc1 ; [2H]c1c([2H])c(Cl)c(Cl)c(Nc2ccc(C(C)(C)C)cc2)c1[2H]]

In a reactor, <A-1> (35.3 g), <A-2a> (23 g), palladium(II) acetate (0.69 g), BINAP (1.92 g), sodium tert-butoxide (29.6 g), and toluene (350 mL) were stirred together for 2 hours under reflux. The mixture was cooled to room temperature and subjected into layer separation with toluene, and the organic layer was collected and concentrated in a vacuum. Purification by silica gel column chromatography afforded <A-2>. (42 g, 91.6%)

### Synthesis Example 1-3 Synthesis of A-3

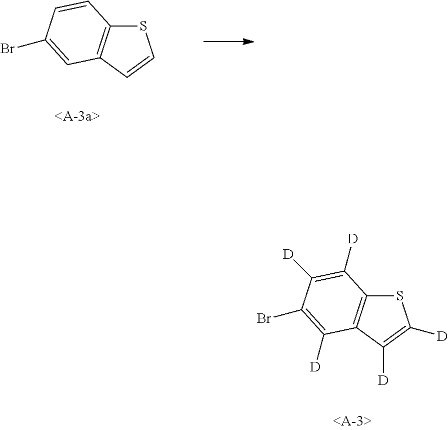 [SMILES: Brc1ccc2sccc2c1 ; [2H]c1sc2c([2H])c([2H])c(Br)c([2H])c2c1[2H]]

The same procedure as in Synthesis Example 1-1, with the exception of using <A-3a> instead of <A-1a>, was carried out to afford <A-3>. (yield 96.1%)

### Synthesis Example 1-4 Synthesis of A-4

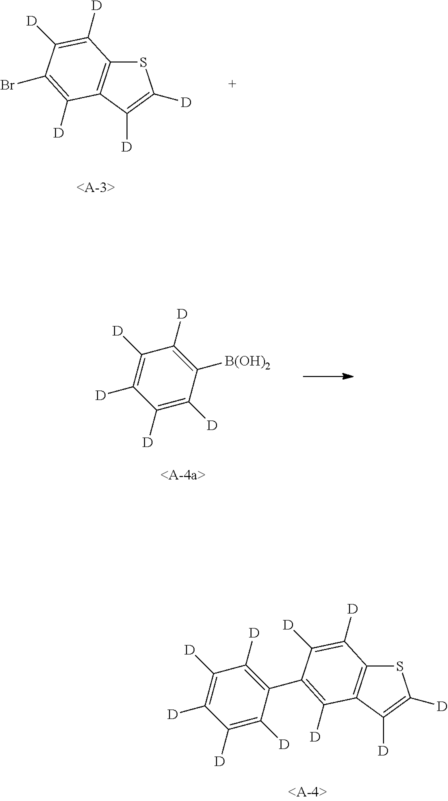 [SMILES: [2H]c1sc2c([2H])c([2H])c(Br)c([2H])c2c1[2H] ; [2H]c1c([2H])c([2H])c(B(O)O)c([2H])c1[2H] ; [2H]c1sc2c([2H])c([2H])c(-c3c([2H])c([2H])c([2H])c([2H])c3[2H])c([2H])c2c1[2H]]

In a reactor, <A-3> (106 g), <A-4a> (74 g), tetrakis (triphenylphosphine)palladium (22.4 g), potassium carbonate (201 g), toluene (530 mL), ethanol (318 mL), and distilled water (212 mL) were stirred together for 16 hours under reflex. The reaction mixture was cooled to room temperature and subjected into layer separation with toluene, and the organic layer was collected and concentrated in a vacuum. Purification by silica gel column chromatography afforded <A-4>. (87.8 g, 82%)

### Synthesis Example 1-5 Synthesis of A-5

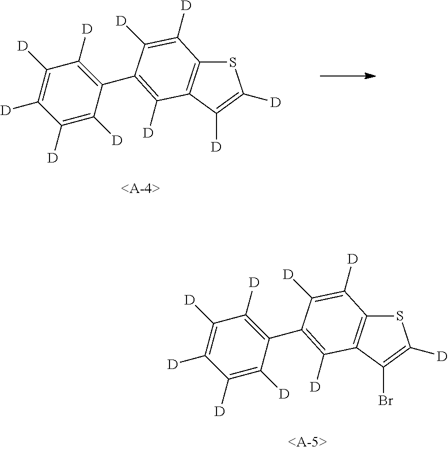 [SMILES: [2H]c1sc2c([2H])c([2H])c(-c3c([2H])c([2H])c([2H])c([2H])c3[2H])c([2H])c2c1[2H] ; [2H]c1sc2c([2H])c([2H])c(-c3c([2H])c([2H])c([2H])c([2H])c3[2H])c([2H])c2c1Br]

In a reactor, <A-4> (45.7 g) and dimethylformamide (230 mL) were stirred together at room temperature. The mixture was added with N-bromosuccinimide (40.6 g) and heated to 50° C., followed by stirring for 16 hours under reflux. The reaction mixture was subjected to layer separation with ethyl acetate. The organic layer was washed with water and concentrated in a vacuum. Purification by silica gel column chromatography afforded <A-5>. (61.1 g, 98.8%)

### Synthesis Example 1-6: Synthesis of A-6

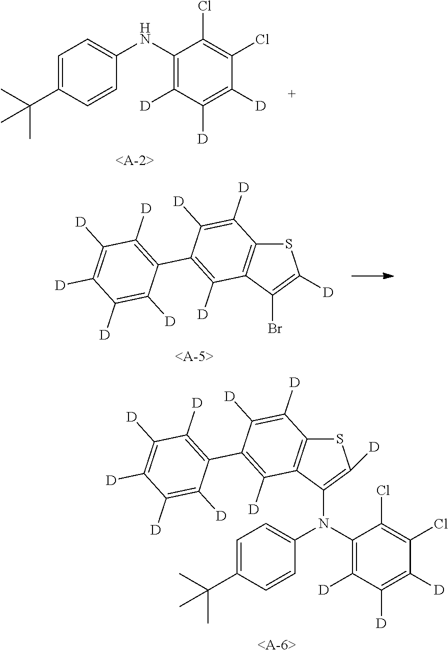 [SMILES: [2H]c1c([2H])c(Cl)c(Cl)c(Nc2ccc(C(C)(C)C)cc2)c1[2H] ; [2H]c1sc2c([2H])c([2H])c(-c3c([2H])c([2H])c([2H])c([2H])c3[2H])c([2H])c2c1Br ; [2H]c1sc2c([2H])c([2H])c(-c3c([2H])c([2H])c([2H])c([2H])c3[2H])c([2H])c2c1N(c1ccc(C(C)(C)C)cc1)c1c([2H])c([2H])c([2H])c(Cl)c1Cl]

In a reactor, <A-2> (47.3 g), <A-5> (61.2 g), bis(tri-tert-butylphosphine)palladium (1.63 g), sodium tert-butoxide (30.6 g), and toluene (470 mL) were stirred together for 16 hours under reflex. The reaction mixture was cooled to room temperature and subjected into layer separation with toluene, and the organic layer was collected and concentrated in a vacuum. Purification by silica gel column chromatography afforded <A-6>. (75 g, 91.6%)

### Synthesis Example 1-7 Synthesis of A-7

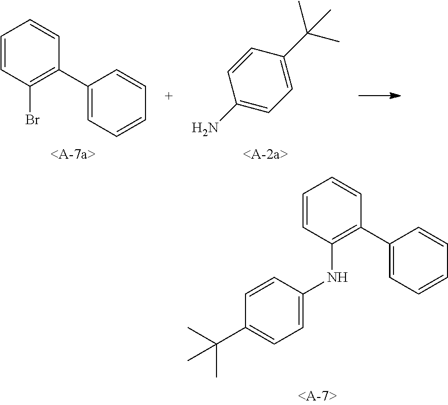 [SMILES: Brc1ccccc1-c1ccccc1 ; CC(C)(C)c1ccc(N)cc1 ; CC(C)(C)c1ccc(Nc2ccccc2-c2ccccc2)cc1]

The same procedure as in Synthesis Example 1-2, with the exception of using <A-7a> instead of <A-1>, was carried out to afford <A-7>. (yield 85.1%)

### Synthesis Example 1-8 Synthesis of A-8

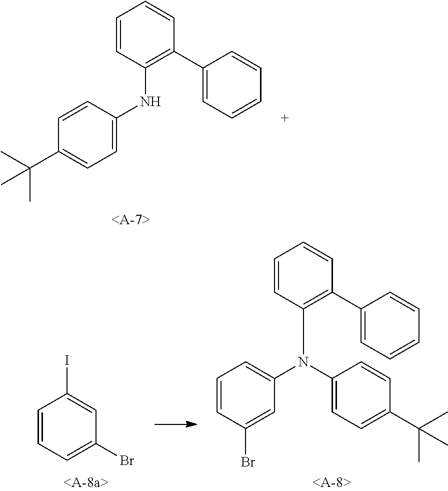 [SMILES: CC(C)(C)c1ccc(Nc2ccccc2-c2ccccc2)cc1 ; Brc1cccc(I)c1 ; CC(C)(C)c1ccc(N(c2cccc(Br)c2)c2ccccc2-c2ccccc2)cc1]

In a reactor, <A-7> (50 g), <A-8a> (56.3 g), palladium(II)acetate (0.4 g), sodium tert-butoxide (23.9 g), xantphos (1 g), and toluene (500 mL) were stirred together for 16 hours under reflex. The reaction mixture was cooled to room temperature and added with ethyl acetate and water, and the organic layer was collected. Purification by silica gel column chromatography afforded <A-8>. (35 g, 46.2%)

### Synthesis Example 1-9: Synthesis of A-9

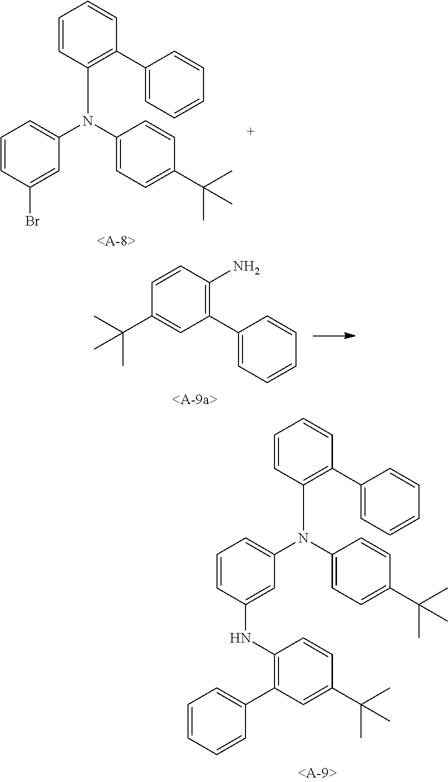 [SMILES: CC(C)(C)c1ccc(N(c2cccc(Br)c2)c2ccccc2-c2ccccc2)cc1 ; CC(C)(C)c1ccc(N)c(-c2ccccc2)c1 ; CC(C)(C)c1ccc(N(c2cccc(Nc3ccc(C(C)(C)C)cc3-c3ccccc3)c2)c2ccccc2-c2ccccc2)cc1]

The same procedure as in Synthesis Example 1-2, with the exception of using <A-8> and <A-9a> instead of <A-1> and <A-2a>, respectively, was carried out to afford <A-9>. (yield 89.4%)

### Synthesis Example 1-10 Synthesis of A-10

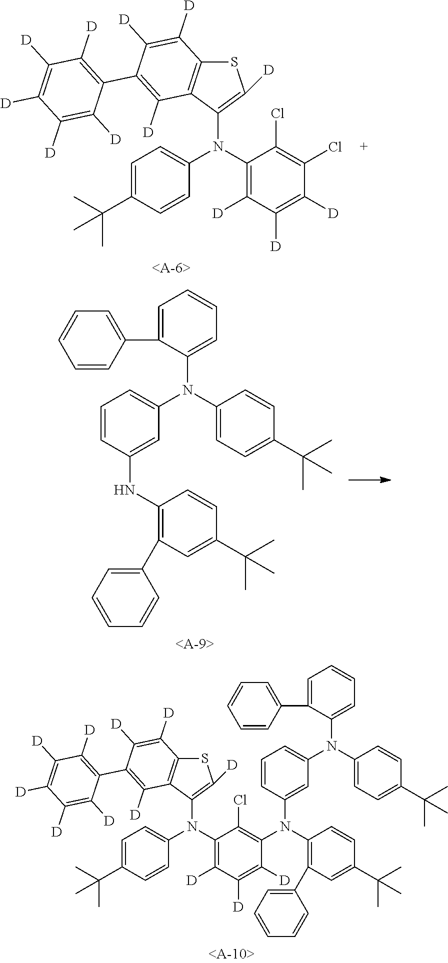 [SMILES: [2H]c1sc2c([2H])c([2H])c(-c3c([2H])c([2H])c([2H])c([2H])c3[2H])c([2H])c2c1N(c1ccc(C(C)(C)C)cc1)c1c([2H])c([2H])c([2H])c(Cl)c1Cl ; CC(C)(C)c1ccc(N(c2cccc(Nc3ccc(C(C)(C)C)cc3-c3ccccc3)c2)c2ccccc2-c2ccccc2)cc1 ; [2H]c1sc2c([2H])c([2H])c(-c3c([2H])c([2H])c([2H])c([2H])c3[2H])c([2H])c2c1N(c1ccc(C(C)(C)C)cc1)c1c([2H])c([2H])c([2H])c(N(c2cccc(N(c3ccc(C(C)(C)C)cc3)c3ccccc3-c3ccccc3)c2)c2ccc(C(C)(C)C)cc2-c2ccccc2)c1Cl]

In a reactor, <A-6> (30 g), <A-9> (30.8 g), bis(tri-tert-butylphosphine) palladium (0.91 g), sodium tert-butoxide (9.6 g), and toluene (300 mL) were stirred together for 16 hours under reflex. The reaction mixture was cooled to room temperature and subjected into layer separation with toluene, and the organic layer was collected and concentrated in a vacuum. Purification by silica gel column chromatography afforded <A-10>. (52.9 g, 84.1%)

### Synthesis Example 1-11: Synthesis of [BD-1]

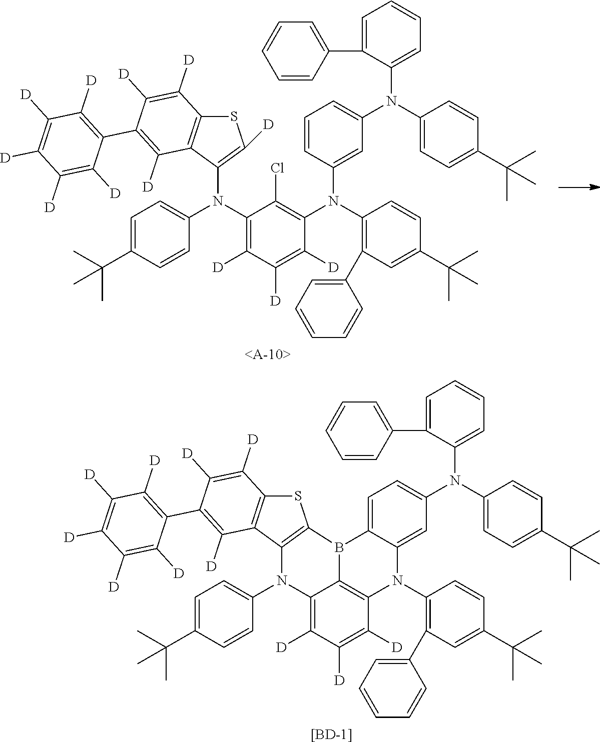

In a reactor, <A-10> (24.6 g), tert-butylbenzene (246 mL) was dropwise added with 1.7 M tert-butyl lithium (40.6 mL) at −60° C. After the temperature was elevated to 60° C., the mixture was stirred for 2 hours and then chilled to −60° C. Boron tribromide (4.9 mL) was dropwise added. The mixture was heated to room temperature, stirred for one hour, cooled to 0° C., and then added with drops of N, N-diisopropylethylamine (8.0 mL). After temperature elevation to 120° C., the reaction mixture was stirred for 16 hours, cooled to room temperature, and added with water (76 mL) and sodium acetate (3.8 g). Ethyl acetate was used to extract an organic layer which was then concentrated in a vacuum and purified through silica gel chromatography to afford [BD-1]. (4.2 g, 17.5%)

MS (MALDI-TOF): m/z 1050.58 [M⁺]

### Synthesis Example 2: Synthesis of [BD-2]

### Synthesis Example 2-1 Synthesis of B-1

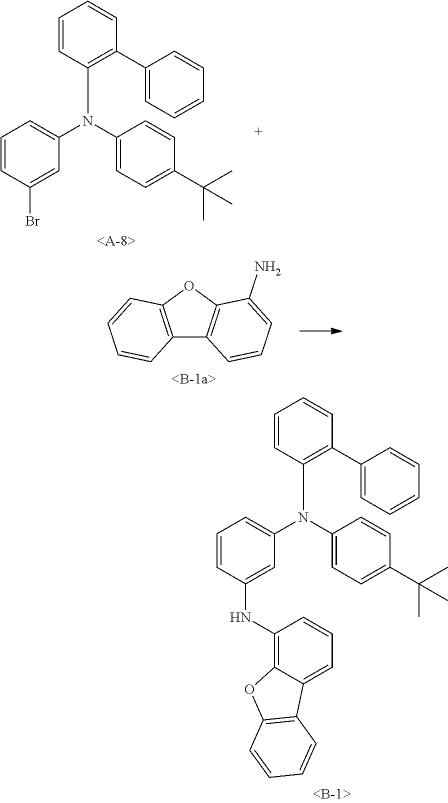 [SMILES: CC(C)(C)c1ccc(N(c2cccc(Br)c2)c2ccccc2-c2ccccc2)cc1 ; Nc1cccc2c1oc1ccccc12 ; CC(C)(C)c1ccc(N(c2cccc(Nc3cccc4c3oc3ccccc34)c2)c2ccccc2-c2ccccc2)cc1]

The same procedure as in Synthesis Example 1-9, with the exception of using <B-1a> instead of <A-9a>, was carried out to afford <B-1>. (yield 90.4%)

### Synthesis Example 2-2 Synthesis of B-2

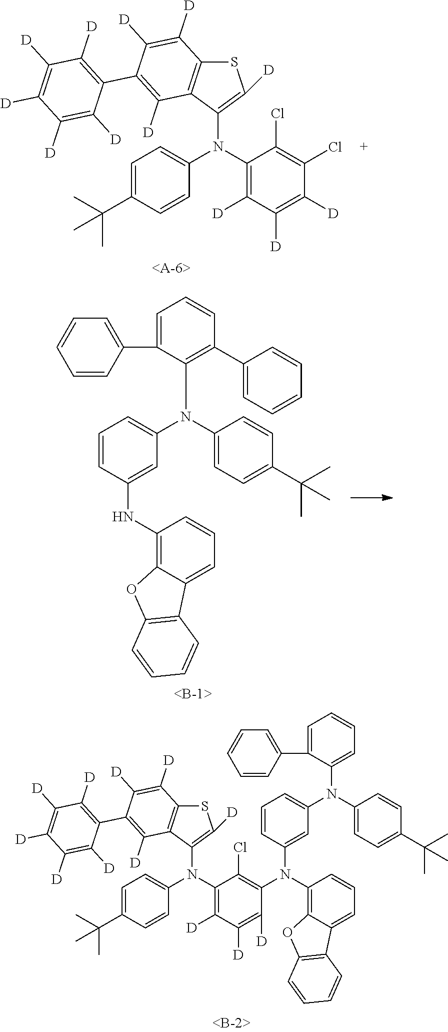 [SMILES: [2H]c1sc2c([2H])c([2H])c(-c3c([2H])c([2H])c([2H])c([2H])c3[2H])c([2H])c2c1N(c1ccc(C(C)(C)C)cc1)c1c([2H])c([2H])c([2H])c(Cl)c1Cl ; CC(C)(C)c1ccc(N(c2cccc(Nc3cccc4c3oc3ccccc34)c2)c2c(-c3ccccc3)cccc2-c2ccccc2)cc1 ; [2H]c1sc2c([2H])c([2H])c(-c3c([2H])c([2H])c([2H])c([2H])c3[2H])c([2H])c2c1N(c1ccc(C(C)(C)C)cc1)c1c([2H])c([2H])c([2H])c(N(c2cccc(N(c3ccc(C(C)(C)C)cc3)c3ccccc3-c3ccccc3)c2)c2cccc3c2oc2ccccc23)c1Cl]

The same procedure as in Synthesis Example 1-10, with the exception of using <B-1> instead of <A-9>, was carried out to afford <B-2>. (yield 87.2%)

### Synthesis Example 2-3 Synthesis of BD-21

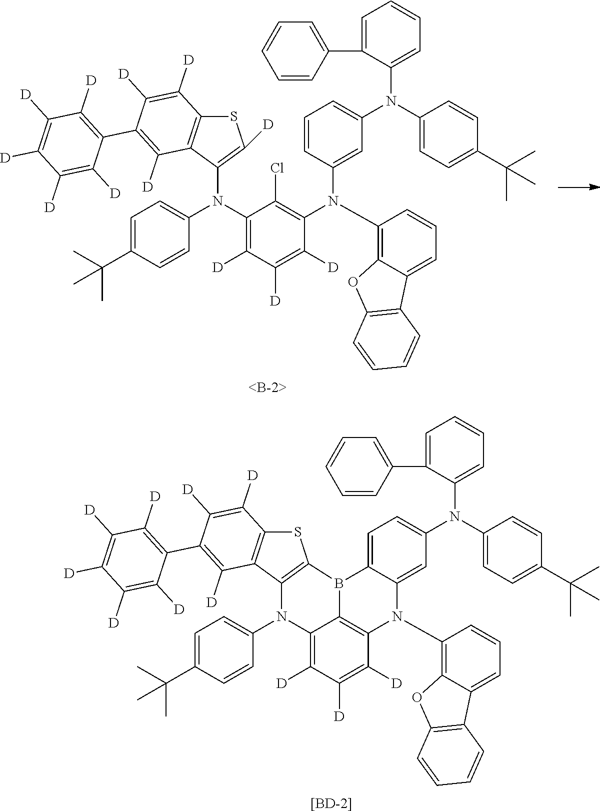

The same procedure as in Synthesis Example 1-11, with the exception of using <B-2> instead of <A-10>, was carried out to afford [BD-2]. (yield 16.4%)

MS (MALDI-TOF): m/z 1008.49 [M⁺]

### Synthesis Example 3: Synthesis of [BD-3]

### Synthesis Example 3-1: Synthesis of C-1

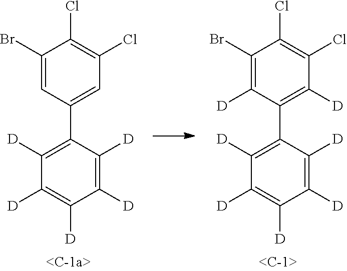 [SMILES: [2H]c1c([2H])c([2H])c(-c2cc(Cl)c(Cl)c(Br)c2)c([2H])c1[2H] ; [2H]c1c([2H])c([2H])c(-c2c([2H])c(Cl)c(Cl)c(Br)c2[2H])c([2H])c1[2H]]

The same procedure as in Synthesis Example 1-1, with the exception of using <C-1a> instead of <A-1a> was carried out to afford <C-1>. (yield 95.9%)

### Synthesis Example 3-2 Synthesis of C-2

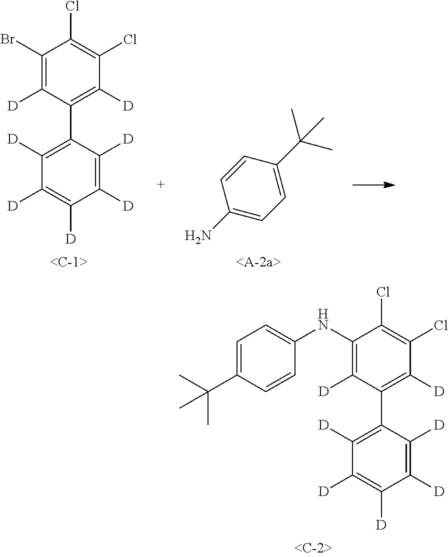 [SMILES: [2H]c1c([2H])c([2H])c(-c2c([2H])c(Cl)c(Cl)c(Br)c2[2H])c([2H])c1[2H] ; CC(C)(C)c1ccc(N)cc1 ; [2H]c1c([2H])c([2H])c(-c2c([2H])c(Cl)c(Cl)c(Nc3ccc(C(C)(C)C)cc3)c2[2H])c([2H])c1[2H]]

The same procedure as in Synthesis Example 1-2, with the exception of using <C-1> instead of <A-1>, was carried out to afford <C-2>. (yield 96.6%)

### Synthesis Example 3-3 Synthesis of C-3

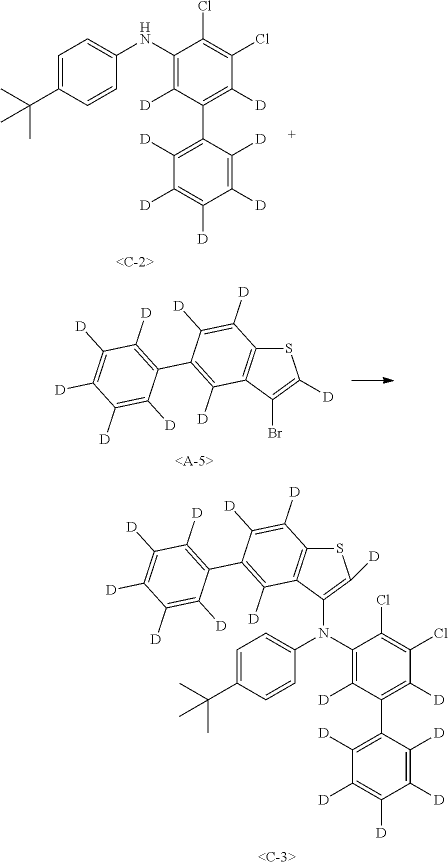 [SMILES: [2H]c1c([2H])c([2H])c(-c2c([2H])c(Cl)c(Cl)c(Nc3ccc(C(C)(C)C)cc3)c2[2H])c([2H])c1[2H] ; [2H]c1sc2c([2H])c([2H])c(-c3c([2H])c([2H])c([2H])c([2H])c3[2H])c([2H])c2c1Br ; [2H]c1sc2c([2H])c([2H])c(-c3c([2H])c([2H])c([2H])c([2H])c3[2H])c([2H])c2c1N(c1ccc(C(C)(C)C)cc1)c1c([2H])c(-c2c([2H])c([2H])c([2H])c([2H])c2[2H])c([2H])c(Cl)c1Cl]

The same procedure as in Synthesis Example 1-6, with the exception of using <C-2> instead of <A-2> was carried out to afford <C-3>. (yield 86.3%)

### Synthesis Example 3-4 Synthesis of C-4

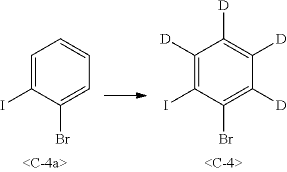 [SMILES: Brc1ccccc1I ; [2H]c1c([2H])c([2H])c(I)c(Br)c1[2H]]

The same procedure as in Synthesis Example 1-1, with the exception of using <C-4a> instead of <A-1a> was carried out to afford <C-4>. (yield 96.1%)

### Synthesis Example 3-5: Synthesis of C-5

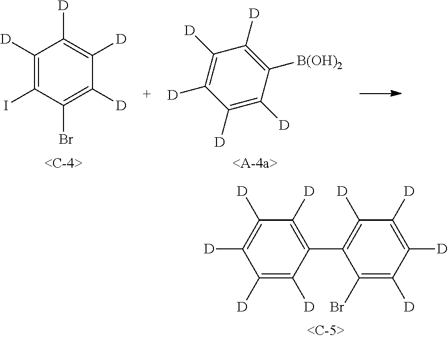 [SMILES: [2H]c1c([2H])c([2H])c(I)c(Br)c1[2H] ; [2H]c1c([2H])c([2H])c(B(O)O)c([2H])c1[2H] ; [2H]c1c([2H])c([2H])c(-c2c([2H])c([2H])c([2H])c([2H])c2Br)c([2H])c1[2H]]

The same procedure as in Synthesis Example 1-4, with the exception of using <C-4> instead of <A-3>, was carried out to afford <C-5>. (yield 96.1%)

### Synthesis Example 3-6 Synthesis of C-6

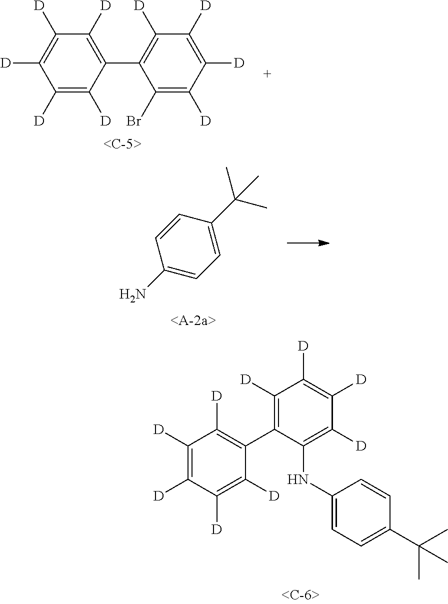 [SMILES: [2H]c1c([2H])c([2H])c(-c2c([2H])c([2H])c([2H])c([2H])c2Br)c([2H])c1[2H] ; CC(C)(C)c1ccc(N)cc1 ; [2H]c1c([2H])c([2H])c(-c2c([2H])c([2H])c([2H])c([2H])c2Nc2ccc(C(C)(C)C)cc2)c([2H])c1[2H]]

The same procedure as in Synthesis Example 1-2, with the exception of using <C-5> instead of <A-1>, was carried out to afford <C-6>. (yield 89.3%)

### Synthesis Example 3-7 Synthesis of C-7

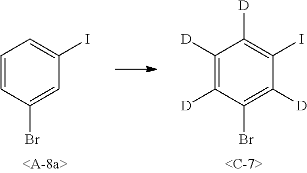 [SMILES: Brc1cccc(I)c1 ; [2H]c1c([2H])c(Br)c([2H])c(I)c1[2H]]

The same procedure as in Synthesis Example 1-1, with the exception of using <A-8a> instead of <A-1a>, was carried out to afford <C-7>. (yield 95.9%)

### Synthesis Example 3-8: Synthesis of C-8

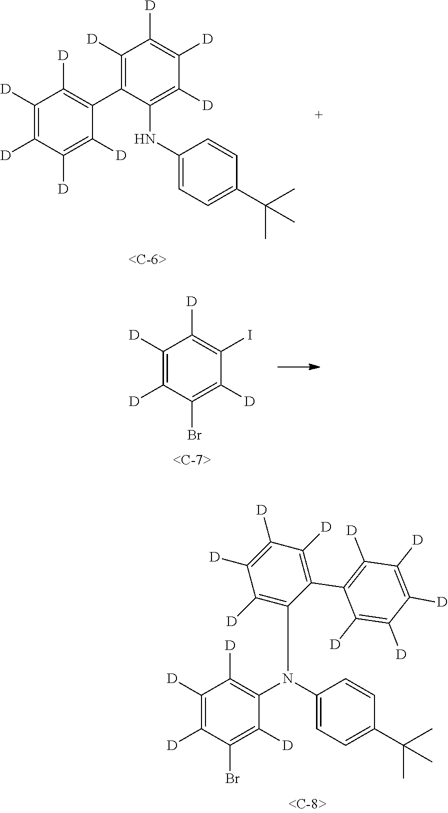 [SMILES: [2H]c1c([2H])c([2H])c(-c2c([2H])c([2H])c([2H])c([2H])c2Nc2ccc(C(C)(C)C)cc2)c([2H])c1[2H] ; [2H]c1c([2H])c(Br)c([2H])c(I)c1[2H] ; [2H]c1c([2H])c([2H])c(-c2c([2H])c([2H])c([2H])c([2H])c2N(c2ccc(C(C)(C)C)cc2)c2c([2H])c([2H])c([2H])c(Br)c2[2H])c([2H])c1[2H]]

The same procedure as in Synthesis Example 1-8, with the exception of using <C-6> and <C-7> instead of <A-7> and <A-8a>, respectively, was carried out to afford <C-8>. (yield 63.5%)

### Synthesis Example 3-9: Synthesis of C-9

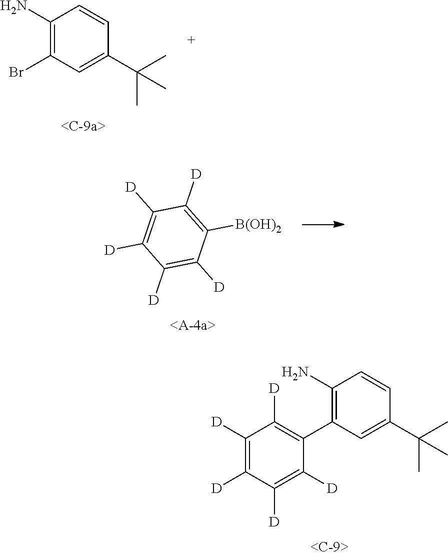 [SMILES: CC(C)(C)c1ccc(N)c(Br)c1 ; [2H]c1c([2H])c([2H])c(B(O)O)c([2H])c1[2H] ; [2H]c1c([2H])c([2H])c(-c2cc(C(C)(C)C)ccc2N)c([2H])c1[2H]]

The same procedure as in Synthesis Example 1-4, with the exception of using <C-9a> instead of <A-3>, was carried out to afford <C-9>. (yield 81.1%)

### Synthesis Example 3-10 Synthesis of C-10

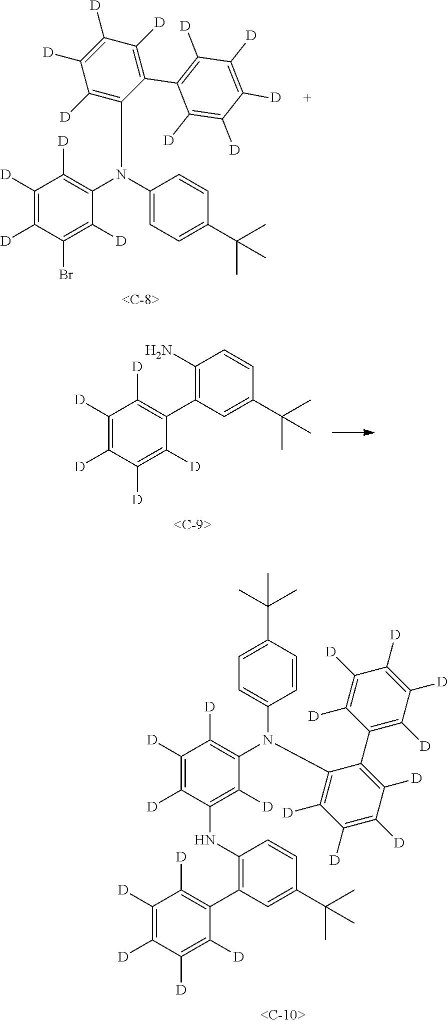 [SMILES: [2H]c1c([2H])c([2H])c(-c2c([2H])c([2H])c([2H])c([2H])c2N(c2ccc(C(C)(C)C)cc2)c2c([2H])c([2H])c([2H])c(Br)c2[2H])c([2H])c1[2H] ; [2H]c1c([2H])c([2H])c(-c2cc(C(C)(C)C)ccc2N)c([2H])c1[2H] ; [2H]c1c([2H])c([2H])c(-c2cc(C(C)(C)C)ccc2Nc2c([2H])c([2H])c([2H])c(N(c3ccc(C(C)(C)C)cc3)c3c([2H])c([2H])c([2H])c([2H])c3-c3c([2H])c([2H])c([2H])c([2H])c3[2H])c2[2H])c([2H])c1[2H]]

The same procedure as in Synthesis Example 1-2, with the exception of using <C-8> and <C-9> instead of <A-1> and <A-2a>, respectively, was carried out to afford <C-10>. (yield 83.7%)

### Synthesis Example 3-11: Synthesis of C-11

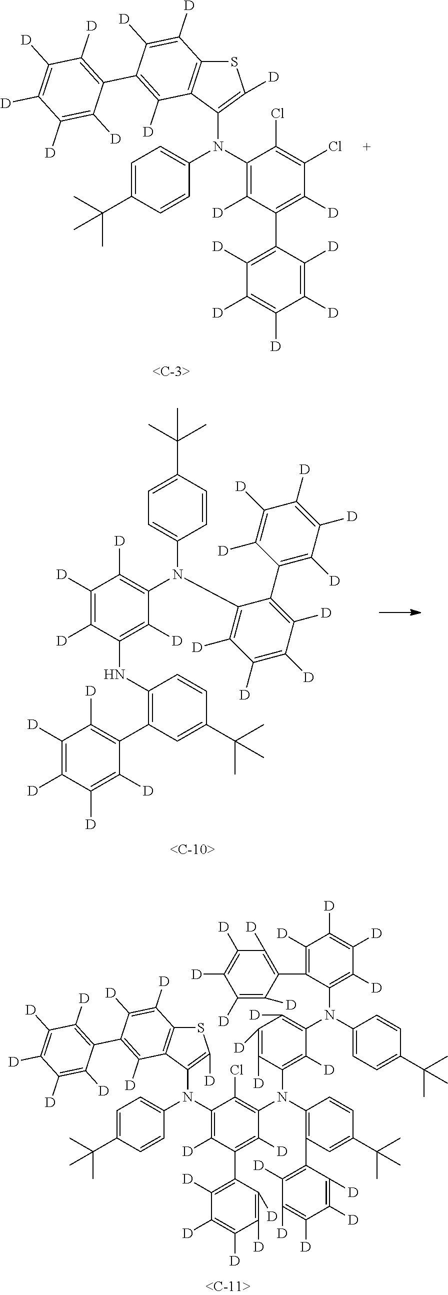

The same procedure as in Synthesis Example 1-10, with the exception of using <C-3> and <C-10> instead of <A-6> and <A-9>, respectively, was carried out to afford <C-11>. (yield 85.4%)

### Synthesis Example 3-12: Synthesis of [BD-3]

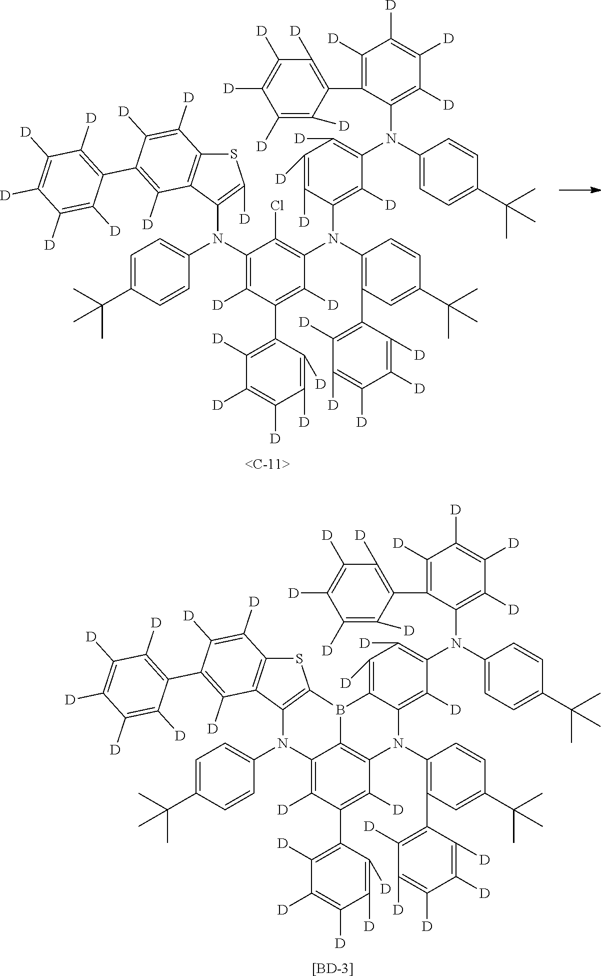

The same procedure as in Synthesis Example 1-11, with the exception of using <C-11> instead of <A-10>, was carried out to afford [BD-3]. (yield 16.4%)

MS (MALDI-TOF): m/z 1147.74 [M⁺]

### Synthesis Example 4: Synthesis of [BD-4]

### Synthesis Example 4-1 Synthesis of D-1

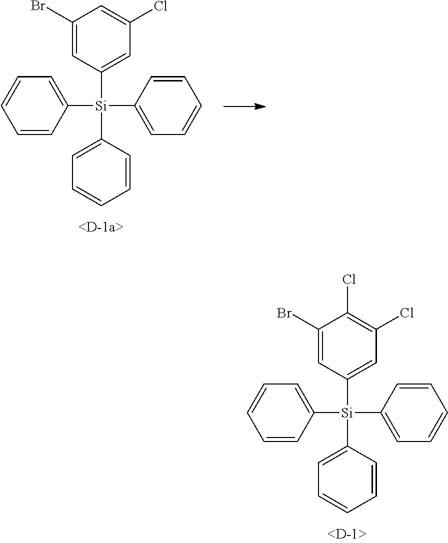 [SMILES: Clc1cc(Br)cc([Si](c2ccccc2)(c2ccccc2)c2ccccc2)c1 ; Clc1cc([Si](c2ccccc2)(c2ccccc2)c2ccccc2)cc(Br)c1Cl]

In a reactor, <D-1a> (50 g) and tetrahydrofuran (50 mL) were added with drops of 2.0 M lithium diisopropylamide (140 mL) at −78° C. and stirred together for 3 hours at the same temperature. After hexachloroethane was slowly added, the mixture was heated to room temperature and stirred for 16 hours. Layer separation was made by adding ethyl acetate and water, and the organic layer was separated and purified through silica gel chromatography to afford <D-1>. (42.5 g, 78.9%)

### Synthesis Example 4-2 Synthesis of D-2

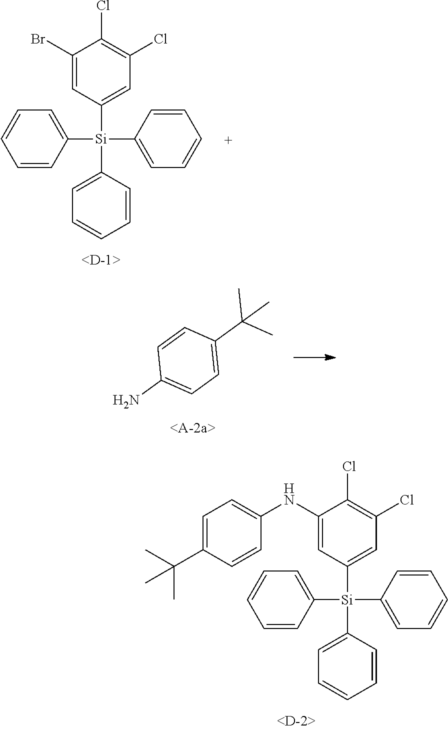 [SMILES: Clc1cc([Si](c2ccccc2)(c2ccccc2)c2ccccc2)cc(Br)c1Cl ; CC(C)(C)c1ccc(N)cc1 ; CC(C)(C)c1ccc(Nc2cc([Si](c3ccccc3)(c3ccccc3)c3ccccc3)cc(Cl)c2Cl)cc1]

The same procedure as in Synthesis Example 1-2, with the exception of using <D-1> instead of <A-1>, was carried out to afford <D-2>. (yield 56%)

### Synthesis Example 4-3: Synthesis of D-3

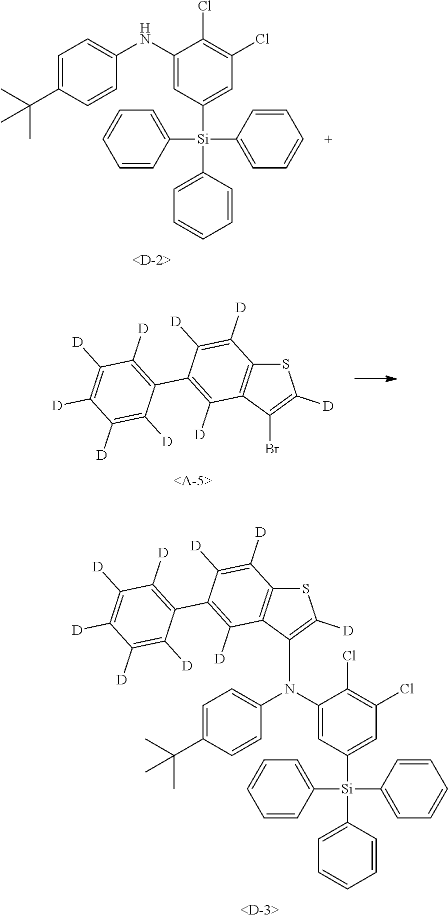 [SMILES: CC(C)(C)c1ccc(Nc2cc([Si](c3ccccc3)(c3ccccc3)c3ccccc3)cc(Cl)c2Cl)cc1 ; [2H]c1sc2c([2H])c([2H])c(-c3c([2H])c([2H])c([2H])c([2H])c3[2H])c([2H])c2c1Br ; [2H]c1sc2c([2H])c([2H])c(-c3c([2H])c([2H])c([2H])c([2H])c3[2H])c([2H])c2c1N(c1ccc(C(C)(C)C)cc1)c1cc([Si](c2ccccc2)(c2ccccc2)c2ccccc2)cc(Cl)c1Cl]

The same procedure as in Synthesis Example 1-6, with the exception of using <D-2> instead of <A-2>, was carried out to afford <D-3>. (yield 89.7%)

### Synthesis Example 4-4 Synthesis of D-4

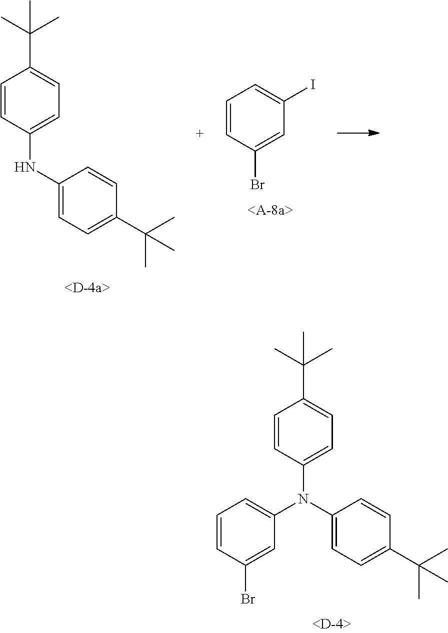 [SMILES: CC(C)(C)c1ccc(Nc2ccc(C(C)(C)C)cc2)cc1 ; Brc1cccc(I)c1 ; CC(C)(C)c1ccc(N(c2ccc(C(C)(C)C)cc2)c2cccc(Br)c2)cc1]

The same procedure as in Synthesis Example 1-8, with the exception of using <D-4a> instead of <A-7>, was carried out to afford <D-4>. (yield 71%)

### Synthesis Example 4-5 Synthesis of D-5

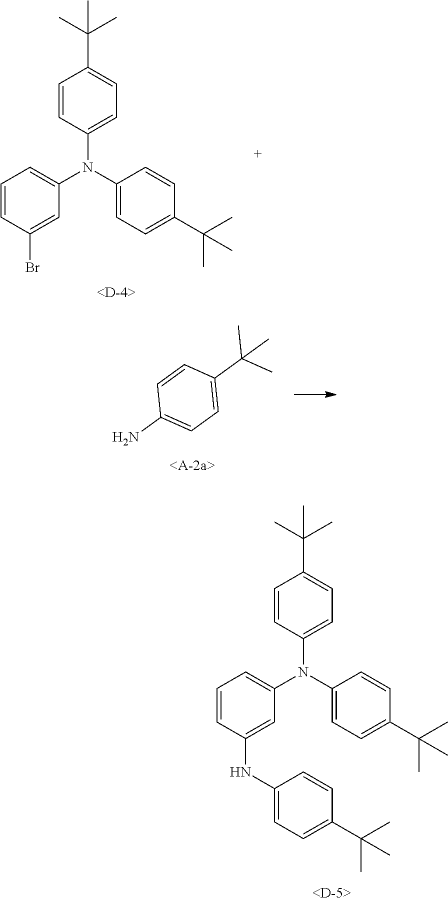 [SMILES: CC(C)(C)c1ccc(N(c2ccc(C(C)(C)C)cc2)c2cccc(Br)c2)cc1 ; CC(C)(C)c1ccc(N)cc1 ; CC(C)(C)c1ccc(Nc2cccc(N(c3ccc(C(C)(C)C)cc3)c3ccc(C(C)(C)C)cc3)c2)cc1]

The same procedure as in Synthesis Example 1-2, with the exception of using <D-4> instead of <A-1>, was carried out to afford <D-5>. (yield 84.7%)

### Synthesis Example 4-6 Synthesis of D-6

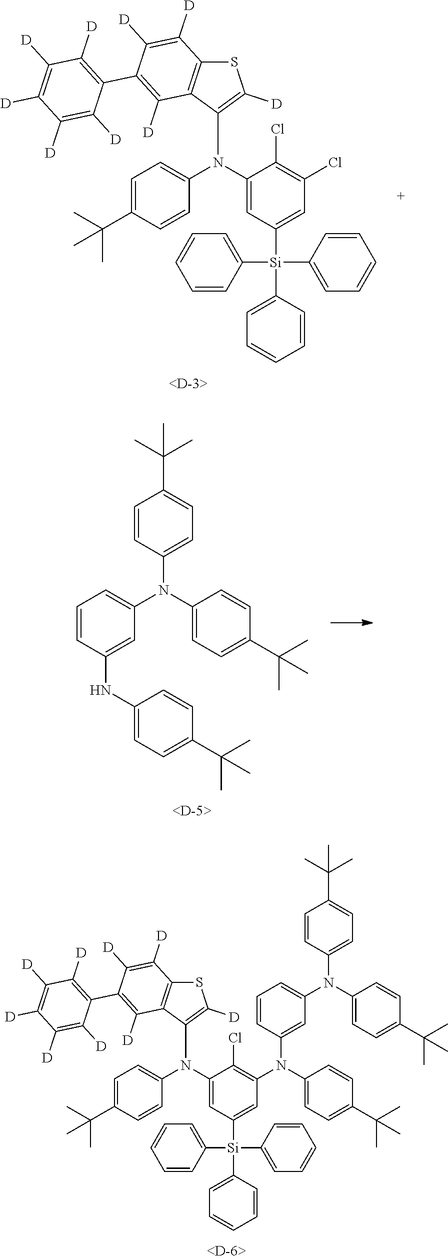 [SMILES: [2H]c1sc2c([2H])c([2H])c(-c3c([2H])c([2H])c([2H])c([2H])c3[2H])c([2H])c2c1N(c1ccc(C(C)(C)C)cc1)c1cc([Si](c2ccccc2)(c2ccccc2)c2ccccc2)cc(Cl)c1Cl ; CC(C)(C)c1ccc(Nc2cccc(N(c3ccc(C(C)(C)C)cc3)c3ccc(C(C)(C)C)cc3)c2)cc1 ; [2H]c1sc2c([2H])c([2H])c(-c3c([2H])c([2H])c([2H])c([2H])c3[2H])c([2H])c2c1N(c1ccc(C(C)(C)C)cc1)c1cc([Si](c2ccccc2)(c2ccccc2)c2ccccc2)cc(N(c2ccc(C(C)(C)C)cc2)c2cccc(N(c3ccc(C(C)(C)C)cc3)c3ccc(C(C)(C)C)cc3)c2)c1Cl]

The same procedure as in Synthesis Example 1-10, with the exception of using <D-3> and <D-5> instead of <A-6> and <A-9>, respectively, was carried out to afford <D-6>. (yield 93.2%)

### Synthesis Example 4-7: Synthesis of [BD-4]

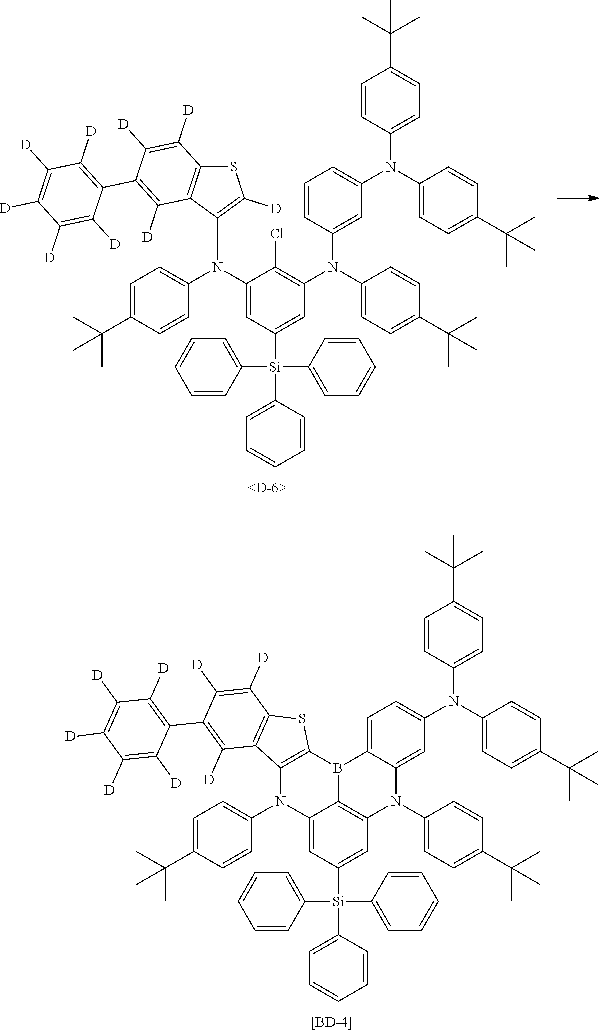

The same procedure as in Synthesis Example 1-11, with the exception of using <D-6> instead of <A-10>, was carried out to afford [BD-4]. (yield 13.7%)

MS (MALDI-TOF): m/z 1209.64 [M⁺]

### SYNTHESIS EXAMPLE 5: Synthesis of [BD-5]

### Synthesis Example 5-1: Synthesis of [BD-5]

The same procedure as in Synthesis Example 1, with the exception of using 5-Bromothieno[2,3-b] pyridine instead of <A-3a> in Synthesis Example 1-3, was carried out to afford [BD-5]. (final yield 13.4%)

MS (MALDI-TOF) m/z 1050.57 [M⁺]

### Examples 1 to 5 Fabrication of Organic Light-Emitting Diodes

An ITO glass substrate was patterned to have a translucent area of 2 mm×2 mm and cleansed. After the ITO glass was mounted in a vacuum chamber that was then set to have a base pressure of 1×10⁻⁷ torr. On the ITO glass substrate, the electron acceptor of the following structural formula [Acceptor-1] and the compound of [Chemical Formula F] were deposited at a ratio of [Acceptor-1]: [Chemical Formula F]=2:98 to form a film (100 Å). Films were formed of [Chemical Formula F] for a hole transport layer (550 Å) and [Chemical Formula G] for an electron barrier layer (50 Å). A light-emitting layer (200 Å) was formed of a mixture including the host [BH-1] and the compounds (2 wt %) according to the present disclosure. Then, films were sequentially formed of [Chemical Formula H] for a hole barrier layer (50 Å), a mixture of [Chemical Formula E-1] and [Chemical Formula E-2] at a ratio of 1:1 for an electron transport layer (250 Å), and [Chemical Formula E-2] for an electron injection layer (10 Å), and then covered with an A₁ layer (1000 Å) to fabricate organic light-emitting diodes. The organic light-emitting diodes thus obtained were measured at 0.4 mA for luminescence properties.

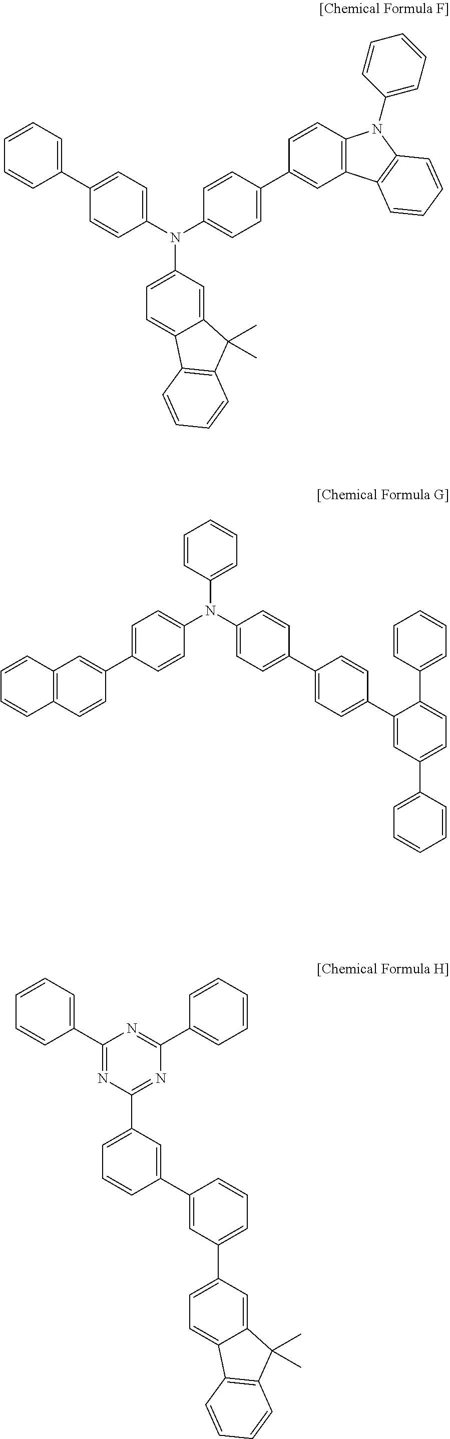 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21]

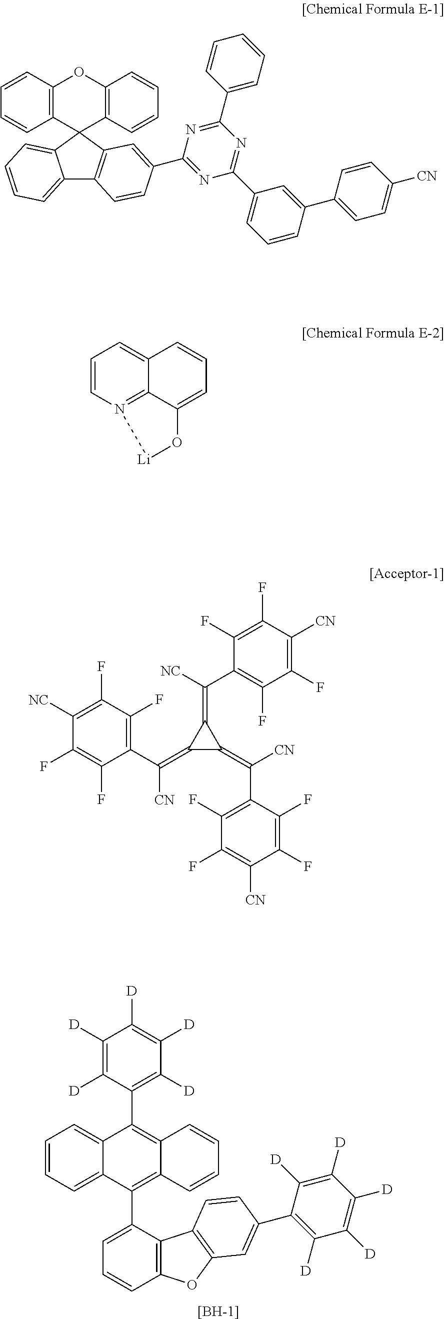

### Comparative Examples 1 to 5

Organic light emitting diodes were fabricated in the same manner as in the Examples, with the exception that [BD-A] to [BD-E] were used instead of the dopant compounds in the Examples. The luminescence of the organic light-emitting diodes thus obtained was measured at 0.4 mA. Structures of [BD-A] to [BD-E] are as follows:

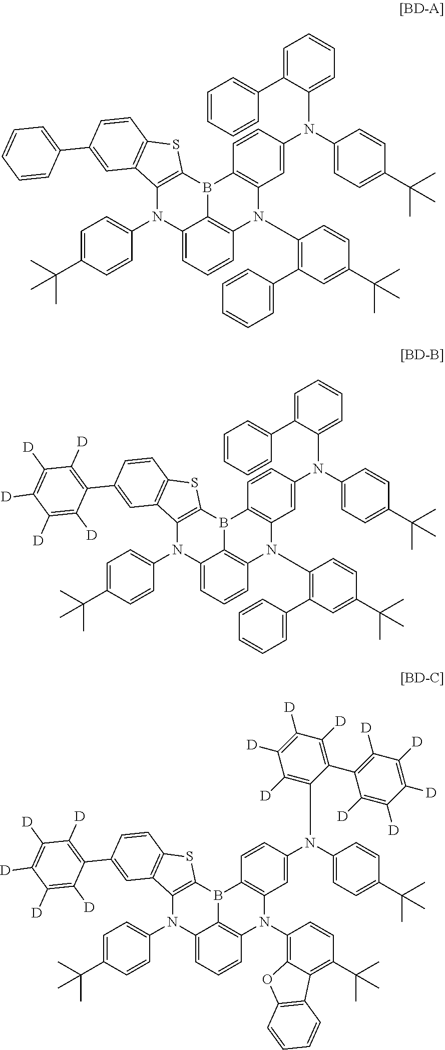

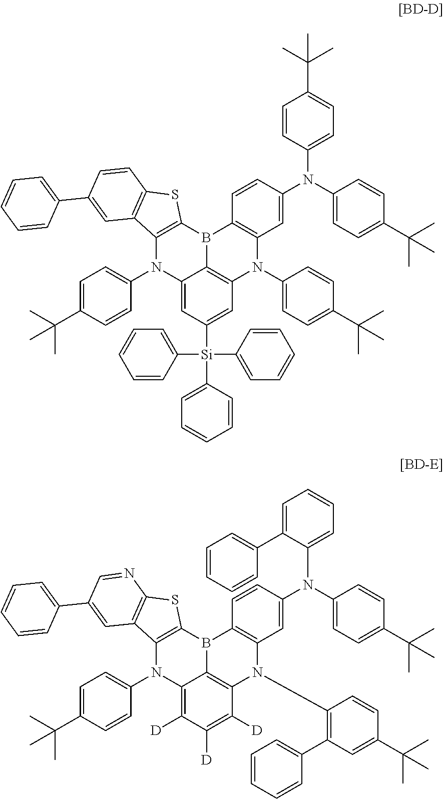 [SMILES: CC(C)(C)c1ccc(N(c2ccc(C(C)(C)C)cc2)c2ccc3c(c2)N(c2ccc(C(C)(C)C)cc2)c2cc([Si](c4ccccc4)(c4ccccc4)c4ccccc4)cc4c2B3c2sc3ccc(-c5ccccc5)cc3c2N4c2ccc(C(C)(C)C)cc2)cc1 ; [2H]c1c([2H])c2c3c(c1[2H])N(c1ccc(C(C)(C)C)cc1)c1c(sc4ncc(-c5ccccc5)cc14)B3c1ccc(N(c3ccc(C(C)(C)C)cc3)c3ccccc3-c3ccccc3)cc1N2c1ccc(C(C)(C)C)cc1-c1ccccc1]

The organic light-emitting diodes fabricated according to Examples 1 to 5 and Comparative Examples 1 to 5 were measured for voltage, external quantum efficiency, and life time, and the measurements are summarized in Table 1, below.

TABLE 1

| | | | Voltage | Efficiency | Lifetime |
|---|---|---|---|---|---|
| Ex. No. | Host | Dopant | (V) | (EQE, %) | (T97, hr) |
| Ex. 1 | BH-1 | [BD-1] | 3.3 | 10.5 | 241 |
| Ex. 2 | BH-1 | [BD-2] | 3.3 | 10.9 | 235 |
| Ex. 3 | BH-1 | [BD-3] | 3.3 | 10.6 | 272 |
| Ex. 4 | BH-1 | [BD-4] | 3.5 | 10.3 | 257 |
| Ex. 5 | BH-1 | [BD-5] | 3.5 | 9.9 | 226 |
| C. Ex. 1 | BH-1 | BD-A | 3.3 | 10.5 | 192 |
| C. Ex. 2 | BH-1 | BD-B | 3.3 | 10.5 | 214 |
| C. Ex. 3 | BH-1 | BD-C | 3.3 | 10.9 | 221 |
| C. Ex. 4 | BH-1 | BD-D | 3.5 | 10.3 | 224 |
| C. Ex. 5 | BH-1 | BD-E | 3.5 | 9.9 | 199 |

As proven in the Examples, the compounds BD-1 to BD-5 could be synthesized at excellent yield from the deuterated aryl halide or heteroaryl halide intermediates because many processes are unnecessary. In addition, the data of Table 1 show higher longevity of the organic light-emitting diodes that employed the compounds BD-1 to BD-5 as dopant materials than the compounds of Comparative Examples 1 to 5 (BD-A to BD-E), demonstrating high applicability of the compounds of the present disclosure to organic electroluminescence devices.

What is claimed is:

1. A method for manufacturing a polycyclic ring compound, the method comprising the steps of:
a) deuterating a compound represented by [Intermediate A-1] to prepare a compound represented by [Intermediate A-2]; and
b) preparing a compound represented by [Chemical Formula A] or [Chemical Formula B] from the compound represented by [Intermediate A-2]: 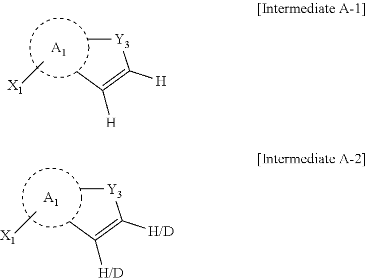
X₁ is any one halogen element selected from among F, Cl, Br, and I,
Y₃ is any one selected from among N—R₁, CR₂R₃, O, S, Se, and SiR₄R₅,
wherein the substituents R₁ to R₅, which can be same or different, are as defined in [Chemical Formula A] and [Chemical Formula B],
A₁ is a substituted or unsubstituted aromatic ring of 6 to 50 carbon atoms or a substituted or unsubstituted heteroaromatic ring of 2 to 50 carbon atoms,
at least one of the hydrogen atoms bonded to the aromatic carbon atoms of the A₁ ring in [Intermediate A-2] is substituted by a deuterium atom,
H/D means that a hydrogen atom or a deuterium atom bonds to a carbon atom; 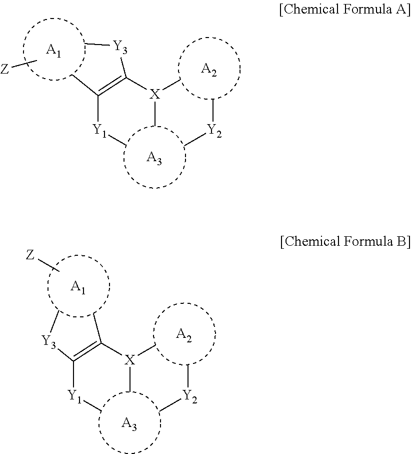
wherein,
A₁'s, which can be same or different, are each independently a substituted or unsubstituted aromatic ring of 6 to 50 carbon atoms or a substituted or unsubstituted heteroaromatic ring of 2 to 50 carbon atoms, with at least one aromatic carbon atom of the A₁ ring moiety being deuterated,
A₂ and A₃, which can be same or different, are each independently at least one selected from among a substituted or unsubstituted aromatic ring of 6 to 50 carbon atoms, a substituted or unsubstituted aliphatic ring-fused aromatic ring of 8 to 50 carbon atoms, a substituted or unsubstituted heteroaromatic ring of 2 to 50 carbon atoms, and a substituted or unsubstituted aliphatic ring-fused heteroaromatic ring of 4 to 50 carbon atoms,
X is any one selected from among B, P, P═O, and P═S,
Z is a substituent for X₁ of [Intermediate A-2], and is selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, and a halogen atom,
Y₁ to Y₃, which can be same or different, are each independently any one selected from among N—R₁, CR₂R₃, O, S, Se, and SiR₄R₅,
wherein R₁ to R₅, which can be same or different, are each independently any one selected from a hydrogen atom, a deuterium atom, a substituted or unsubstituted alkyl of 1 to 30 carbon atoms, a substituted or unsubstituted alkenyl of 2 to 24 carbon atoms, a substituted or unsubstituted alkynyl of 2 to 24 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 1 to 30 carbon atoms, a substituted or unsubstituted heteroaryl of 2 to 50 carbon atoms, a substituted or unsubstituted alkoxyl of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen,
a bond may be formed between R₂ and R₃ to additionally form a mono- or polycyclic aliphatic or aromatic ring and/or a bond may be formed between R₄ and R₅ to additionally form a mono- or polycyclic aliphatic or aromatic ring,
any of the substituents R₁ to R₅ in Y₁ can bond to the A₃ ring moiety to form an additional mono- or polycyclic aliphatic or aromatic ring,
any of the substituents R₁ to R₅ in Y₂ can bond to the A₂ or A₃ ring moiety to form an additional mono- or polycyclic aliphatic or aromatic ring,
any of the substituents R₁ to R₅ in Y₃ can bond to the A₁ ring moiety to additionally form an additional mono- or polycyclic aliphatic or aromatic ring, and
in [Chemical Formula B],
at least any one of R₁ to R₅ in Y₁ can bond to at least any one of R₁ to R₅ in Y₃ to additionally form a mono- or polycyclic aliphatic or aromatic ring,
wherein the term ‘substituted’ in the expression “a substituted or unsubstituted” in [Intermediate A-1], [Intermediate A-2], [Chemical Formula A] and [Chemical Formula B] means having at least one substituent selected from the group consisting of a deuterium atom, a cyano, a halogen, a hydroxy, a nitro, an alkyl of 1 to 24 carbon atoms, a deuterated alkyl of 1 to 24 carbon atoms, a halogenated alkyl of 1 to 24 carbon atoms, an alkenyl of 2 to 24 carbon atoms, an alkynyl of 2 to 24 carbon atoms, a cycloalkyl of 3 to 24 carbon atoms, a deuterated cycloalkyl of 3 to 24 carbon atoms, a heteroalkyl of 1 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, a heteroarylalkyl of 2 to 24 carbon atoms, a deuterated heteroarylalkyl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, a deuterated aryloxy of 6 to 24 carbon atoms, an arylthionyl of 6 to 24 carbon atoms, and a deuterated arylthionyl of 6 to 24 carbon atoms.

2. The method of claim 1, wherein the method comprises the steps of:
a) deuterating a compound represented by [Intermediate A-3] to prepare a compound represented by [Intermediate A-4]; and
b) preparing a compound represented by [Chemical Formula A-1] or [Chemical Formula B-1] from the compound represented by [Intermediate A-4]: 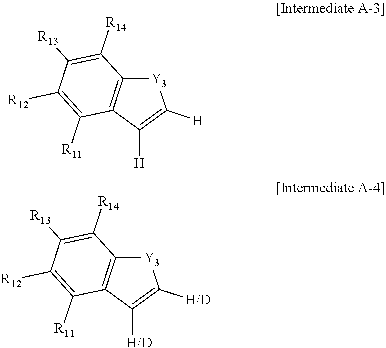
wherein,
R₁₁ to R₁₄, which can be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, a deuterium-substituted or unsubstituted arylthionyl of 6 to 24 carbon atoms, with a proviso that one of the substituents R₁₁ to R₁₄ is a halogen atom selected from among F, Cl, Br, and I,
Y₃ is any one selected from among N—R₁, CR₂R₃, O, S, Se, and SiR₄R₅, as defined above,
wherein at least one of the three, non-halogen substituents among R₁₁ to R₁₄ in [Intermediate A-4] is a deuterium atom, and
H/D means that a hydrogen atom or a deuterium atom bonds to a carbon atom; 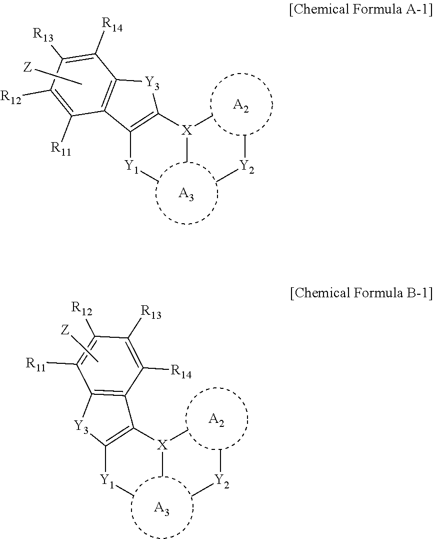
wherein,
R₁₁ to R₁₄, which can be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms,
Z is a substituent for the halogen atom accounting for one of R₁₁ to R₁₄ in [Intermediate A-4], and is selected from among a hydrogen atom, a deuterium atom, a deuterium-substituted or unsubstituted alkyl of 1 to 30 carbon atoms, a deuterium-substituted or unsubstituted aryl of 6 to 50 carbon atoms, a deuterium-substituted or unsubstituted cycloalkyl of 3 to 30 carbon atoms, a deuterium-substituted or unsubstituted heteroaryl of 2 to 50 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, and a halogen atom, and
wherein one of R₁₁ to R₁₄ is Z and at least one of the three substituents, which are not Z, among R₁₁ to R₁₄ is a deuterium atom, and
the A₂ ring moiety, the A₃ ring moiety, X, and Y₁ to Y₃ are each as defined in claim 1.

3. The method of claim 1, wherein the step b) is adapted to leave X₁ from [Intermediate A-2] and bond Z to the same leaving site to form [Intermediate A-2-1], as illustrated in the following [Reaction Scheme A-2]: 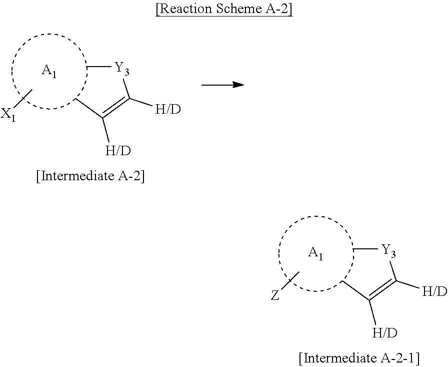
wherein,
X₁ is a halogen element selected from among F, Cl, Br, and I,
Z is a substituent for X₁ of [Intermediate A-2], and is selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted aromatic ring-fused cycloalkyl of 7 to 30 carbon atoms, a substituted or unsubstituted heteroaromatic ring-fused cycloalkyl of 5 to 30 carbon atoms, a substituted or unsubstituted aromatic ring-fused heterocycloalkyl of 6 to 30 carbon atoms, a substituted or unsubstituted aliphatic ring-fused aryl of 8 to 30 carbon atoms, a substituted or unsubstituted aliphatic ring-fused heteroaryl of 5 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, and a halogen atom, and
the A₁ ring and Y₃ are each as defined in claim 1,
wherein at least one of the hydrogen atoms bonded to the aromatic carbon atoms of the A₁ ring is substituted by a deuterium atom.

4. The method of claim 2, wherein step b) comprises leaving a halogen atom responsible for any one of the substituents R₁₁ to R₁₄ from [Intermediate A-4] and bonding Z to [Intermediate A-4] to form [Intermediate A-4-1], as illustrated in [Reaction Scheme A-4], below: 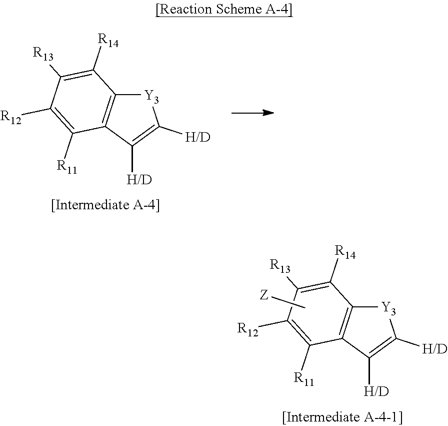
wherein,
Y₃ is as defined in Intermediate A-4 of claim 2,
R₁₁ to R₁₄ in [Intermediate A-4], which can be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms, with a proviso that one of the substituents R₁₁ to R₁₄ is a halogen atom selected from among F, Cl, Br, and I,
wherein at least one of the three, non-halogen substituents among R₁₁ to R₁₄ is a deuterium atom,
R₁₁ to R₁₄ in [Intermediate A-4-1], which can be same or different, are each independently any one selected from the group consisting of a hydrogen atom, a deuterium atom, a cyano, a halogen, a hydroxy, a nitro, a deuterium-substituted or unsubstituted alkyl of 1 to 24 carbon atoms, a deuterium-substituted or unsubstituted halogenated alkyl of 1 to 24 carbon atoms, a deuterium-substituted or unsubstituted alkenyl of 2 to 24 carbon atoms, a deuterium-substituted or unsubstituted alkynyl of 2 to 24 carbon atoms, a deuterium-substituted or unsubstituted cycloalkyl of 3 to 24 carbon atoms, a deuterium-substituted or unsubstituted heteroalkyl of 1 to 24 carbon atoms, a deuterium-substituted or unsubstituted aryl of 6 to 24 carbon atoms, a deuterium-substituted or unsubstituted arylalkyl of 7 to 24 carbon atoms, a deuterium-substituted or unsubstituted alkylaryl of 7 to 24 carbon atoms, a deuterium-substituted or unsubstituted heteroaryl of 2 to 24 carbon atoms, a deuterium-substituted or unsubstituted heteroarylalkyl of 2 to 24 carbon atoms, a deuterium-substituted or unsubstituted alkoxy of 1 to 24 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, a deuterium-substituted or unsubstituted germyl of 0 to 30 carbon atoms, a deuterium-substituted or unsubstituted aryloxy of 6 to 24 carbon atoms, and a deuterium-substituted or unsubstituted arylthionyl of 6 to 24 carbon atoms,
Z is a substituent for the halogen atom accounting for one of R₁₁ to R₁₄ in [Intermediate A-4], and is selected from among a hydrogen atom, a deuterium atom, a deuterium-substituted or unsubstituted alkyl of 1 to 30 carbon atoms, a deuterium-substituted or unsubstituted aryl of 6 to 50 carbon atoms, a deuterium-substituted or unsubstituted cycloalkyl of 3 to 30 carbon atoms, a deuterium-substituted or unsubstituted heteroaryl of 2 to 50 carbon atoms, a deuterium-substituted or unsubstituted aromatic ring-fused cycloalkyl of 7 to 30 carbon atoms, a deuterium-substituted or unsubstituted heteroaromatic ring-fused cycloalkyl of 5 to 30 carbon atoms, a deuterium-substituted or unsubstituted aromatic ring-fused heterocycloalkyl of 6 to 30 carbon atoms, a deuterium-substituted or unsubstituted aliphatic ring-fused aryl of 8 to 30 carbon atoms, a deuterium-substituted or unsubstituted aliphatic ring-fused heteroaryl of 5 to 30 carbon atoms, a deuterium-substituted or unsubstituted amine of 0 to 30 carbon atoms, a deuterium-substituted or unsubstituted silyl of 0 to 30 carbon atoms, and a deuterium-substituted or unsubstituted germyl of 0 to 30 carbon atoms, and a halogen,
wherein one of R₁₁ to R₁₄ is Z and at least one of the three substituents, which are not Z, among R₁₁ to R₁₄ is a deuterium atom.

5. The method of claim 1, wherein all of the hydrogen atoms bonded to the aromatic carbon atoms of the A₁ ring in [Chemical Formula A] and [Chemical Formula B] are substituted by deuterium atoms.

6. The method of claim 2, wherein three of the substituents Ru to R₁₄ in [Chemical Formula A-1] and [Chemical Formula B-1], are each a deuterium atom when the three substituents are not Z.

7. The method of claim 1, wherein the substituent Z in [Chemical Formula A], [Chemical Formula B], [Chemical Formula A-1], and [Chemical Formula B-1] is a substituted or unsubstituted aryl of 6 to 20 carbon atoms.

8. The method of claim 2, wherein the substituent Z in [Chemical Formula A], [Chemical Formula B], [Chemical Formula A-1], and [Chemical Formula B-1] is a substituted or unsubstituted aryl of 6 to 20 carbon atoms.

9. The method of claim 1, wherein at least one of the substituents Y₁ and Y₂ in [Chemical Formula A], [Chemical Formula B], [Chemical Formula A-1], and [Chemical Formula B-1] is NR₁.

10. The method of claim 2, wherein at least one of the substituents Y₁ and Y₂ in [Chemical Formula A], [Chemical Formula B], [Chemical Formula A-1], and [Chemical Formula B-1] is NR₁.

11. The method of claim 9, wherein the R₁ is a substituted or unsubstituted aryl of 6 to 50 carbon atoms or a substituted or unsubstituted heteroaryl of 2 to 50 carbon atoms.

12. The method of claim 10, wherein the R₁ is a substituted or unsubstituted aryl of 6 to 50 carbon atoms or a substituted or unsubstituted heteroaryl of 2 to 50 carbon atoms.

13. The method of claim 9, wherein the linkers Y₁ and Y₂ in [Chemical Formula A] and [Chemical Formula B] are same or different and at least one of the linkers is a linker represented by the following [Structural Formula A]: 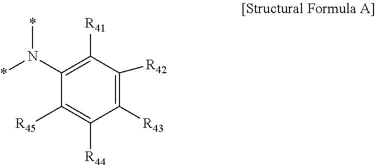
wherein
“-*” denotes a bonding site at which the N atom is bonded to the ethenyl carbon atom connected to Y₁, an aromatic carbon atom in A₂ ring moiety, or an aromatic carbon atom in A₃ ring moiety; and
R₄₁ to R₄₅, which can be same or different, are each independently any one selected from among a deuterium atom, a cyano, a halogen, an alkyl of 1 to 24 carbon atoms, a deuterated alkyl of 1 to 24 carbon atoms, a cycloalkyl of 3 to 24 carbon atoms, a deuterated cycloalkyl of 3 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, an aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, and an arylthionyl of 6 to 24 carbon atoms, and R₄₁ and R₄₅ can each independently be bonded to the A₁, A₂, or A₃ ring moiety to form an additional mono- or polycyclic aliphatic or aromatic ring.

14. The method of claim 10, wherein the linkers Y₁ and Y₂ in [Chemical Formula A] and [Chemical Formula B] are same or different and at least one of the linkers is a linker represented by the following [Structural Formula A]: 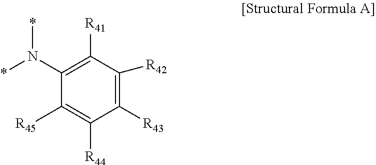
wherein
“-*” denotes a bonding site at which the N atom is bonded to the ethenyl carbon atom connected to Y₁, an aromatic carbon atom in A₂ ring moiety, or an aromatic carbon atom in A₃ ring moiety; and
R₄₁ to R₄₅, which can be same or different, are each independently any one selected from among a deuterium atom, a cyano, a halogen, an alkyl of 1 to 24 carbon atoms, a deuterated alkyl of 1 to 24 carbon atoms, a cycloalkyl of 3 to 24 carbon atoms, a deuterated cycloalkyl of 3 to 24 carbon atoms, an aryl of 6 to 24 carbon atoms, a deuterated aryl of 6 to 24 carbon atoms, an arylalkyl of 7 to 24 carbon atoms, a deuterated arylalkyl of 7 to 24 carbon atoms, an alkylaryl of 7 to 24 carbon atoms, a deuterated alkylaryl of 7 to 24 carbon atoms, a heteroaryl of 2 to 24 carbon atoms, a deuterated heteroaryl of 2 to 24 carbon atoms, an alkoxy of 1 to 24 carbon atoms, an aromatic ring-fused cycloalkyl of 7 to 24 carbon atoms, a deuterated aromatic ring-fused cycloalkyl of 7 to 24 carbon atoms, a heteroaromatic ring-fused cycloalkyl of 5 to 24 carbon atoms, a deuterated heteroaromatic ring-fused cycloalkyl of 5 to 24 carbon atoms, an aromatic ring-fused heterocycloalkyl of 6 to 24 carbon atoms, a deuterated aromatic ring-fused heterocycloalkyl of 6 to 24 carbon atoms, an aliphatic ring-fused aryl of 8 to 24 carbon atoms, a deuterated aliphatic ring-fused aryl of 8 to 30 carbon atoms, an aliphatic ring-fused heteroaryl of 5 to 24 carbon atoms, a deuterated aliphatic ring-fused heteroaryl of 5 to 24 carbon atoms, an amine of 1 to 24 carbon atoms, a deuterated amine of 1 to 24 carbon atoms, a silyl of 1 to 24 carbon atoms, a deuterated silyl of 1 to 24 carbon atoms, a germyl of 1 to 24 carbon atoms, a deuterated germyl of 1 to 24 carbon atoms, an aryloxy of 6 to 24 carbon atoms, and an arylthionyl of 6 to 24 carbon atoms, and R₄₁ and R₄₅ can each independently be bonded to the A₁, A₂, or A₃ ring moiety to form an additional mono- or polycyclic aliphatic or aromatic ring.

15. The method of claim 1, wherein the linker Y₁ in [Chemical Formula A] and [Chemical Formula B] is an oxygen atom (O) or a sulfur atom (S).

16. The method of claim 2, wherein the linker Y₁ in [Chemical Formula A] and [Chemical Formula B] is an oxygen atom (O) or a sulfur atom (S).

17. The method of claim 1, wherein, in [Chemical Formula A], [Chemical Formula B], [Chemical Formula A-1], and [Chemical Formula B-1],
at least one of the hydrogen atoms bonded to the aromatic carbon atoms in the A₂ ring is substituted by a deuterium atom, or
at least one of the hydrogen atoms bonded to the aromatic carbon atoms in the A₃ ring is substituted by a deuterium atom.

18. The method of claim 2, wherein, in [Chemical Formula A], [Chemical Formula B], [Chemical Formula A-1], and [Chemical Formula B-1],
at least one of the hydrogen atoms bonded to the aromatic carbon atoms in the A₂ ring is substituted by a deuterium atom, or
at least one of the hydrogen atoms bonded to the aromatic carbon atoms in the A₃ ring is substituted by a deuterium atom.

19. The method of claim 17, wherein the hydrogen atoms bonded to the aromatic carbon atoms in the A₃ ring moiety in [Chemical Formula A], [Chemical Formula B], [Chemical Formula A-1], and [Chemical Formula B-1] are all substituted by a deuterium atom.

20. The method of claim 18, wherein the hydrogen atoms bonded to the aromatic carbon atoms in the A₃ ring moiety in [Chemical Formula A], [Chemical Formula B], [Chemical Formula A-1], and [Chemical Formula B-1] are all substituted by a deuterium atom.

21. The method of claim 1, wherein the aromatic hydrocarbon ring of 6 to 50 carbon atoms or the heteroaromatic ring of 2 to 50 carbon atoms of at least one of the A₁ to A₃ ring in [Chemical Formula A] and [Chemical Formula B] is bonded to an aryl amino radical represented by the following Structural Formula F: 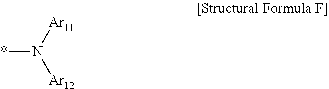
wherein,
“-*” denotes a bonding site participating in forming a bond to a carbon aromatic ring member of any one of A₁ to A₃, and
Ar₁₁ and Ar₁₂, which are same or different, are each independently a substituted or unsubstituted aryl of 6 to 18 carbon atoms and can be linked to each other to form a ring.
